(19) United States
(12) Patent Application Publication
(10) Pub. No.: US 2025/0151400 A1
(43) Pub. Date: May 8, 2025

(54) SEMICONDUCTOR STRUCTURES WITH INTEGRATED ELECTROSTATIC DISCHARGE CLAMP CIRCUITS

(71) Applicant: International Business Machines Corporation, Armonk, NY (US)

(72) Inventors: Lijuan Zou, Slingerlands, NY (US); Tao Li, Slingerlands, NY (US); Ruilong Xie, Niskayuna, NY (US); Nicolas Jean Loubet, Guilderland, NY (US)

(21) Appl. No.: 18/501,129

(22) Filed: Nov. 3, 2023

(51) Int. Cl. H01L 27/12; H01L 27/02

(52) U.S. Cl. CPC H10D 86/60; H10D 86/0214; H10D 86/441; H10D 86/481; H10D 89/911; H10D 89/931

(57) ABSTRACT

A semiconductor structure includes a transistor device at a first side of the semiconductor structure, a control circuit at the first side of the semiconductor structure, and a resistor-capacitor circuit including a resistor and a capacitor. The resistor is in a power delivery network at a second side of the semiconductor structure and the capacitor is at the first side of the semiconductor structure. A first electrode of the capacitor is coupled to a first power rail in the power delivery network at the second side of the semiconductor structure. A second electrode of the capacitor is coupled to a second power rail in the power delivery network at the second side of the semiconductor structure. An input of the control circuit is coupled to the resistor. A gate of the transistor device is coupled to an output of the control circuit.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of Silicon Germanium (SiGe), between sheets of channel material, which may be formed of Silicon (Si).

For continued scaling and area improvement, stacked transistor structures may be used. A stacked transistor structure may include multiple transistors stacked over one another vertically. With stacked transistor structures, for example, vias which extend between the frontside and the backside may have a high aspect ratio. The formation of high aspect ratio vias, however, presents various process challenges.

### SUMMARY

Embodiments of the invention provide techniques for forming semiconductor structures with integrated electrostatic discharge clamp circuits.

In one embodiment, a semiconductor structure comprises a transistor device at a first side of the semiconductor structure, a control circuit at the first side of the semiconductor structure, and a resistor-capacitor circuit comprising a resistor and a capacitor. The resistor is in a power delivery network at a second side of the semiconductor structure and the capacitor is at the first side of the semiconductor structure. A first electrode of the capacitor is coupled to a first power rail in the power delivery network at the second side of the semiconductor structure. A second electrode of the capacitor is coupled to a second power rail in the power delivery network at the second side of the semiconductor structure. An input of the control circuit is coupled to the resistor. A gate of the transistor device is coupled to an output of the control circuit.

The semiconductor structure advantageously provides improved electrostatic discharge capability under electrostatic discharge stress conditions, at least in part through forming the capacitor of the resistor-capacitor circuit on the first side of the semiconductor structure and forming the resistor of the resistor-capacitor circuit on the second side of the semiconductor structure. The semiconductor structure also advantageously allows for the transistor device to be a wide transistor device, such as a wide nanosheet transistor device.

In another exemplary embodiment, as may be combined with the preceding paragraphs, the first power rail may be coupled to a ground voltage and the second power rail may be coupled to a positive supply voltage.

In another exemplary embodiment, as may be combined with the preceding paragraphs, the input of the control circuit may be coupled to the resistor through one or more vias formed through a shallow trench isolation region.

In another exemplary embodiment, as may be combined with the preceding paragraphs, the control circuit may comprise an inverter and the transistor device may comprise a nanosheet transistor structure.

In another embodiment, an electrostatic discharge clamp circuit comprises a resistor-capacitor circuit, a control circuit, and an electrostatic discharge clamp device. The resistor-capacitor circuit comprises a resistor in a backside power delivery network and a capacitor at a frontside of the electrostatic discharge clamp circuit. The capacitor has a first electrode coupled to a first power rail in the backside power delivery network and a second electrode coupled to a first surface of the resistor. A second surface of the resistor, opposite the first surface of the resistor, is coupled to a second power rail in the backside power delivery network. An input of the control circuit is coupled to the resistor. The electrostatic discharge clamp device is coupled to an output of the control circuit.

The electrostatic discharge clamp circuit advantageously provides improved electrostatic discharge capability under electrostatic discharge stress conditions, at least in part through forming the capacitor of the resistor-capacitor circuit in the frontside and forming the resistor of the resistor-capacitor circuit in the backside, such as in the backside power delivery network. The electrostatic discharge clamp circuit also advantageously allows the electrostatic discharge clamp device to be a wide transistor device, such as a wide nanosheet transistor device.

In another exemplary embodiment, as may be combined with the preceding paragraphs, the electrostatic discharge clamp device comprises a transistor device coupled between the first power rail and the second power rail. The electrostatic discharge clamp device may comprise two or more transistor devices connected in parallel between the first power rail and the second power rail.

In another embodiment, an integrated circuit comprises an electrostatic discharge clamp circuit structure comprising a transistor device at a first side of the electrostatic discharge clamp circuit structure, a control circuit at the first side of the electrostatic discharge clamp circuit structure, and a resistor-capacitor circuit comprising a resistor and a capacitor. The resistor is in a power delivery network at a second side of the electrostatic discharge clamp circuit structure and the capacitor is at the first side of the electrostatic discharge clamp circuit structure. A first electrode of the capacitor is coupled to a first power rail in the power delivery network at the second side of the electrostatic discharge clamp circuit structure. A second electrode of the capacitor is coupled to a second power rail in the power delivery network at the second side of the electrostatic discharge clamp circuit structure. An input of the control circuit is coupled to the resistor. A gate of the transistor device is coupled to an output of the control circuit.

The electrostatic discharge clamp circuit structure of the integrated circuit advantageously provides improved electrostatic discharge capability under electrostatic discharge stress conditions, at least in part through forming the capacitor of the resistor-capacitor circuit on the first side of the electrostatic discharge clamp circuit structure and forming the resistor of the resistor-capacitor circuit at the second side of the electrostatic discharge clamp circuit structure. The electrostatic discharge clamp circuit structure also advantageously allows for the transistor device to be a wide transistor device, such as a wide nanosheet transistor device.

In another exemplary embodiment, as may be combined with the preceding paragraphs, the first power rail is coupled to a ground voltage and the second power rail is coupled to a positive supply voltage.

In another exemplary embodiment, as may be combined with the preceding paragraphs, the input of the control circuit is coupled to the resistor through one or more vias formed through a shallow trench isolation region.

### BRIEF DESCRIPTION OF THE DRAWINGS

FIG. 1A depicts a first cross-sectional view of a semiconductor structure following patterning of a nanosheet stack and formation of shallow trench isolation regions, according to an embodiment of the invention.

FIG. 1B depicts a second cross-sectional view of semiconductor structure following the patterning of the nanosheet stack and the formation of the shallow trench isolation regions, according to an embodiment of the invention.

FIG. 1C depicts a first top-down view showing where the first and second cross-sectional views of FIGS. 1A and 1B are taken, according to an embodiment of the invention.

FIG. 1D depicts a third cross-sectional view of the semiconductor structure following the patterning of the nanosheet stack and the formation of the shallow trench isolation regions, according to an embodiment of the invention.

FIG. 1E depicts a fourth cross-sectional view of the semiconductor structure following the patterning of the nanosheet stack and the formation of the shallow trench isolation regions, according to an embodiment of the invention.

FIG. 1F depicts a fifth cross-sectional view of the semiconductor structure following the patterning of the nanosheet stack and the formation of the shallow trench isolation regions, according to an embodiment of the invention.

FIG. 1G depicts a second top-down view showing where the third, fourth and fifth cross-sectional views of FIGS. 1D, 1E and 1F are taken, according to an embodiment of the invention.

FIG. 1H depicts a sixth cross-sectional view of the semiconductor structure following the patterning of the nanosheet stack and the formation of the shallow trench isolation regions, according to an embodiment of the invention.

FIG. 1I depicts a third top-down view showing where the sixth cross-sectional view of FIG. 1H is taken, according to an embodiment of the invention.

FIG. 2A depicts a first cross-sectional view of the semiconductor structure of FIGS. 1A-1I following gate backside via patterning, according to an embodiment of the invention.

FIG. 2B depicts a second cross-sectional view of the semiconductor structure of FIGS. 1A-1I following the gate backside via patterning, according to an embodiment of the invention.

FIG. 2C depicts a first top-down view showing where the first and second cross-sectional views of FIGS. 2A and 2B are taken, according to an embodiment of the invention.

FIG. 2D depicts a third cross-sectional view of the semiconductor structure of FIGS. 1A-1I following the gate backside via patterning, according to an embodiment of the invention.

FIG. 2E depicts a fourth cross-sectional view of the semiconductor structure of FIGS. 1A-1I following the gate backside via patterning, according to an embodiment of the invention.

FIG. 2F depicts a fifth cross-sectional view of the semiconductor structure of FIGS. 1A-1I following the gate backside via patterning, according to an embodiment of the invention.

FIG. 2G depicts a second top-down view showing where the third, fourth and fifth cross-sectional views of FIGS. 2D, 2E and 2F are taken, according to an embodiment of the invention.

FIG. 2H depicts a sixth cross-sectional view of the semiconductor structure of FIGS. 1A-1I following the gate backside via patterning, according to an embodiment of the invention.

FIG. 2I depicts a third top-down view showing where the sixth cross-sectional view of FIG. 2H is taken, according to an embodiment of the invention.

FIG. 3A depicts a first cross-sectional view of the semiconductor structure of FIGS. 2A-2I following dummy gate patterning, according to an embodiment of the invention.

FIG. 3B depicts a second cross-sectional view of the semiconductor structure of FIGS. 2A-2I following the dummy gate patterning, according to an embodiment of the invention.

FIG. 3C depicts a first top-down view showing where the first and second cross-sectional views of FIGS. 3A and 3B are taken, according to an embodiment of the invention.

FIG. 3D depicts a third cross-sectional view of the semiconductor structure of FIGS. 2A-2I following the dummy gate patterning, according to an embodiment of the invention.

FIG. 3E depicts a fourth cross-sectional view of the semiconductor structure of FIGS. 1A-1I following the dummy gate patterning, according to an embodiment of the invention.

FIG. 3F depicts a fifth cross-sectional view of the semiconductor structure of FIGS. 2A-2I following the dummy gate patterning, according to an embodiment of the invention.

FIG. 3G depicts a second top-down view showing where the third, fourth and fifth cross-sectional views of FIGS. 3D, 3E and 3F are taken, according to an embodiment of the invention.

FIG. 3H depicts a sixth cross-sectional view of the semiconductor structure of FIGS. 2A-2I following the dummy gate patterning, according to an embodiment of the invention.

FIG. 3I depicts a third top-down view showing where the sixth cross-sectional view of FIG. 3H is taken, according to an embodiment of the invention.

FIG. 4A depicts a first cross-sectional view of the semiconductor structure of FIGS. 3A-3I following removal of a sacrificial layer and deposition of spacer material, according to an embodiment of the invention.

FIG. 4B depicts a second cross-sectional view of the semiconductor structure of FIGS. 3A-3I following the removal of the sacrificial layer and the deposition of the spacer material, according to an embodiment of the invention.

FIG. 4C depicts a first top-down view showing where the first and second cross-sectional views of FIGS. 4A and 4B are taken, according to an embodiment of the invention.

FIG. 4D depicts a third cross-sectional view of the semiconductor structure of FIGS. 3A-3I following the removal of the sacrificial layer and the deposition of the spacer material, according to an embodiment of the invention.

FIG. 4E depicts a fourth cross-sectional view of the semiconductor structure of FIGS. 3A-3I following the removal of the sacrificial layer and the deposition of the spacer material, according to an embodiment of the invention.

FIG. 4F depicts a fifth cross-sectional view of the semiconductor structure of FIGS. 3A-3I following the removal of the sacrificial layer and the deposition of the spacer material, according to an embodiment of the invention.

FIG. 4G depicts a second top-down view showing where the third, fourth and fifth cross-sectional views of FIGS. 4D, 4E and 4F are taken, according to an embodiment of the invention.

FIG. 4H depicts a sixth cross-sectional view of the semiconductor structure of FIGS. 3A-3I following the removal of the sacrificial layer and the deposition of the spacer material, according to an embodiment of the invention.

FIG. 4I depicts a third top-down view showing where the sixth cross-sectional view of FIG. 4H is taken, according to an embodiment of the invention.

FIG. 5A depicts a first cross-sectional view of the semiconductor structure of FIGS. 4A-4I following nanosheet recess and formation of inner spacers, source/drain regions and an interlayer dielectric layer, according to an embodiment of the invention.

FIG. 5B depicts a second cross-sectional view of the semiconductor structure of FIGS. 4A-4I following the nanosheet recess and the formation of the inner spacers, the source/drain regions and the interlayer dielectric layer, according to an embodiment of the invention.

FIG. 5C depicts a first top-down view showing where the first and second cross-sectional views of FIGS. 5A and 5B are taken, according to an embodiment of the invention.

FIG. 5D depicts a third cross-sectional view of the semiconductor structure of FIGS. 4A-4I following the nanosheet recess and the formation of the inner spacers, the source/drain regions and the interlayer dielectric layer, according to an embodiment of the invention.

FIG. 5E depicts a fourth cross-sectional view of the semiconductor structure of FIGS. 4A-4I following the nanosheet recess and the formation of the inner spacers, the source/drain regions and the interlayer dielectric layer, according to an embodiment of the invention.

FIG. 5F depicts a fifth cross-sectional view of the semiconductor structure of FIGS. 4A-4I following the nanosheet recess and the formation of the inner spacers, the source/drain regions and the interlayer dielectric layer, according to an embodiment of the invention.

FIG. 5G depicts a second top-down view showing where the third, fourth and fifth cross-sectional views of FIGS. 5D, 5E and 5F are taken, according to an embodiment of the invention.

FIG. 5H depicts a sixth cross-sectional view of the semiconductor structure of FIGS. 4A-4I following the nanosheet recess and the formation of the inner spacers, the source/drain regions and the interlayer dielectric layer, according to an embodiment of the invention.

FIG. 5I depicts a third top-down view showing where the sixth cross-sectional view of FIG. 5H is taken, according to an embodiment of the invention.

FIG. 6A depicts a first cross-sectional view of the semiconductor structure of FIGS. 5A-5I following removal of the dummy gate from regions where a capacitor will be formed, according to an embodiment of the invention.

FIG. 6B depicts a second cross-sectional view of the semiconductor structure of FIGS. 5A-5I following the removal of the dummy gate from the regions where the capacitor will be formed, according to an embodiment of the invention.

FIG. 6C depicts a first top-down view showing where the first and second cross-sectional views of FIGS. 6A and 6B are taken, according to an embodiment of the invention.

FIG. 6D depicts a third cross-sectional view of the semiconductor structure of FIGS. 5A-5I following the removal of the dummy gate from the regions where the capacitor will be formed, according to an embodiment of the invention.

FIG. 6E depicts a fourth cross-sectional view of the semiconductor structure of FIGS. 5A-5I following the removal of the dummy gate from the regions where the capacitor will be formed, according to an embodiment of the invention.

FIG. 6F depicts a fifth cross-sectional view of the semiconductor structure of FIGS. 5A-5I following the removal of the dummy gate from the regions where the capacitor will be formed, according to an embodiment of the invention.

FIG. 6G depicts a second top-down view showing where the third, fourth and fifth cross-sectional views of FIGS. 6D, 6E and 6F are taken, according to an embodiment of the invention.

FIG. 6H depicts a sixth cross-sectional view of the semiconductor structure of FIGS. 5A-5I following the removal of the dummy gate from the regions where the capacitor will be formed, according to an embodiment of the invention.

FIG. 6I depicts a third top-down view showing where the sixth cross-sectional view of FIG. 6H is taken, according to an embodiment of the invention.

FIG. 7A depicts a first cross-sectional view of the semiconductor structure of FIGS. 6A-6I following removal of the spacer material from the regions where the capacitor will be formed, according to an embodiment of the invention.

FIG. 7B depicts a second cross-sectional view of the semiconductor structure of FIGS. 6A-6I following the removal of the spacer material from the regions where the capacitor will be formed, according to an embodiment of the invention.

FIG. 7C depicts a first top-down view showing where the first and second cross-sectional views of FIGS. 7A and 7B are taken, according to an embodiment of the invention.

FIG. 7D depicts a third cross-sectional view of the semiconductor structure of FIGS. 6A-6I following the removal of the spacer material from the regions where the capacitor will be formed, according to an embodiment of the invention.

FIG. 7E depicts a fourth cross-sectional view of the semiconductor structure of FIGS. 6A-6I following the removal of the spacer material from the regions where the capacitor will be formed, according to an embodiment of the invention.

FIG. 7F depicts a fifth cross-sectional view of the semiconductor structure of FIGS. 6A-6I following the removal of the spacer material from the regions where the capacitor will be formed, according to an embodiment of the invention.

FIG. 7G depicts a second top-down view showing where the third, fourth and fifth cross-sectional views of FIGS. 7D, 7E and 7F are taken, according to an embodiment of the invention.

FIG. 7H depicts a sixth cross-sectional view of the semiconductor structure of FIGS. 6A-6I following the removal of the spacer material from the regions where the capacitor will be formed, according to an embodiment of the invention.

FIG. 7I depicts a third top-down view showing where the sixth cross-sectional view of FIG. 7H is taken, according to an embodiment of the invention.

FIG. 8A depicts a first cross-sectional view of the semiconductor structure of FIGS. 7A-7I following formation of a bottom electrode layer for the capacitor, a dielectric layer and a capping liner layer, according to an embodiment of the invention.

FIG. 8B depicts a second cross-sectional view of the semiconductor structure of FIGS. 7A-7I following the formation of the bottom electrode layer for the capacitor, the dielectric layer and the capping liner layer, according to an embodiment of the invention.

FIG. 8C depicts a first top-down view showing where the first and second cross-sectional views of FIGS. 8A and 8B are taken, according to an embodiment of the invention.

FIG. 8D depicts a third cross-sectional view of the semiconductor structure of FIGS. 7A-7I following the formation of the bottom electrode layer for the capacitor, the dielectric layer and the capping liner layer, according to an embodiment of the invention.

FIG. 8E depicts a fourth cross-sectional view of the semiconductor structure of FIGS. 7A-7I following the formation of the bottom electrode layer for the capacitor, the dielectric layer and the capping liner layer, according to an embodiment of the invention.

FIG. 8F depicts a fifth cross-sectional view of the semiconductor structure of FIGS. 7A-7I following the formation of the bottom electrode layer for the capacitor, the dielectric layer and the capping liner layer, according to an embodiment of the invention.

FIG. 8G depicts a second top-down view showing where the third, fourth and fifth cross-sectional views of FIGS. 8D, 8E and 8F are taken, according to an embodiment of the invention.

FIG. 8H depicts a sixth cross-sectional view of the semiconductor structure of FIGS. 7A-7I following the formation of the bottom electrode layer for the capacitor, the dielectric layer and the capping liner layer, according to an embodiment of the invention.

FIG. 8I depicts a third top-down view showing where the sixth cross-sectional view of FIG. 8H is taken, according to an embodiment of the invention.

FIG. 9A depicts a first cross-sectional view of the semiconductor structure of FIGS. 8A-8I following chamfering of portions of the bottom electrode layer, the dielectric layer and the capping liner layer, according to an embodiment of the invention.

FIG. 9B depicts a second cross-sectional view of the semiconductor structure of FIGS. 8A-8I following the chamfering of the portions of the bottom electrode layer, the dielectric layer and the capping liner layer, according to an embodiment of the invention.

FIG. 9C depicts a first top-down view showing where the first and second cross-sectional views of FIGS. 9A and 9B are taken, according to an embodiment of the invention.

FIG. 9D depicts a third cross-sectional view of the semiconductor structure of FIGS. 8A-8I following the chamfering of the portions of the bottom electrode layer, the dielectric layer and the capping liner layer, according to an embodiment of the invention.

FIG. 9E depicts a fourth cross-sectional view of the semiconductor structure of FIGS. 8A-8I following the chamfering of the portions of the bottom electrode layer, the dielectric layer and the capping liner layer, according to an embodiment of the invention.

FIG. 9F depicts a fifth cross-sectional view of the semiconductor structure of FIGS. 8A-8I following the chamfering of the portions of the bottom electrode layer, the dielectric layer and the capping liner layer, according to an embodiment of the invention.

FIG. 9G depicts a second top-down view showing where the third, fourth and fifth cross-sectional views of FIGS. 9D, 9E and 9F are taken, according to an embodiment of the invention.

FIG. 9H depicts a sixth cross-sectional view of the semiconductor structure of FIGS. 8A-8I following the chamfering of the portions of the bottom electrode layer, the dielectric layer and the capping liner layer, according to an embodiment of the invention.

FIG. 9I depicts a third top-down view showing where the sixth cross-sectional view of FIG. 9H is taken, according to an embodiment of the invention.

FIG. 10A depicts a first cross-sectional view of the semiconductor structure of FIGS. 9A-9I following removal of remaining portions of the dummy gate, the sacrificial layers, and the capping liner layer, according to an embodiment of the invention.

FIG. 10B depicts a second cross-sectional view of the semiconductor structure of FIGS. 9A-9I following the removal of the remaining portions of the dummy gate, the sacrificial layers, and the capping liner layer, according to an embodiment of the invention.

FIG. 10C depicts a first top-down view showing where the first and second cross-sectional views of FIGS. 10A and 10B are taken, according to an embodiment of the invention.

FIG. 10D depicts a third cross-sectional view of the semiconductor structure of FIGS. 9A-9I following the removal of the remaining portions of the dummy gate, the sacrificial layers, and the capping liner layer, according to an embodiment of the invention.

FIG. 10E depicts a fourth cross-sectional view of the semiconductor structure of FIGS. 9A-9I following the removal of the remaining portions of the dummy gate, the sacrificial layers, and the capping liner layer, according to an embodiment of the invention.

FIG. 10F depicts a fifth cross-sectional view of the semiconductor structure of FIGS. 9A-9I following the removal of the remaining portions of the dummy gate, the sacrificial layers, and the capping liner layer, according to an embodiment of the invention.

FIG. 10G depicts a second top-down view showing where the third, fourth and fifth cross-sectional views of FIGS. 10D, 10E and 10F are taken, according to an embodiment of the invention.

FIG. 10H depicts a sixth cross-sectional view of the semiconductor structure of FIGS. 9A-9I following the removal of the remaining portions of the dummy gate, the sacrificial layers, and the capping liner layer, according to an embodiment of the invention.

FIG. 10I depicts a third top-down view showing where the sixth cross-sectional view of FIG. 10H is taken, according to an embodiment of the invention.

FIG. 11A depicts a first cross-sectional view of the semiconductor structure of FIGS. 10A-10I following deposition of a dielectric layer and a reliability anneal, according to an embodiment of the invention.

FIG. 11B depicts a second cross-sectional view of the semiconductor structure of FIGS. 10A-10I following the deposition of the dielectric layer and the reliability anneal, according to an embodiment of the invention.

FIG. 11C depicts a first top-down view showing where the first and second cross-sectional views of FIGS. 11A and 11B are taken, according to an embodiment of the invention.

FIG. 11D depicts a third cross-sectional view of the semiconductor structure of FIGS. 10A-10I following the deposition of the dielectric layer and the reliability anneal, according to an embodiment of the invention.

FIG. 11E depicts a fourth cross-sectional view of the semiconductor structure of FIGS. 10A-10I following the deposition of the dielectric layer and the reliability anneal, according to an embodiment of the invention.

FIG. 11F depicts a fifth cross-sectional view of the semiconductor structure of FIGS. 10A-10I following the deposition of the dielectric layer and the reliability anneal, according to an embodiment of the invention.

FIG. 11G depicts a second top-down view showing where the third, fourth and fifth cross-sectional views of FIGS. 11D, 11E and 11F are taken, according to an embodiment of the invention.

FIG. 11H depicts a sixth cross-sectional view of the semiconductor structure of FIGS. 10A-10I following the deposition of the dielectric layer and the reliability anneal, according to an embodiment of the invention.

FIG. 11I depicts a third top-down view showing where the sixth cross-sectional view of FIG. 11H is taken, according to an embodiment of the invention.

FIG. 12A depicts a first cross-sectional view of the semiconductor structure of FIGS. 11A-11I following formation of a gate stack, according to an embodiment of the invention.

FIG. 12B depicts a second cross-sectional view of the semiconductor structure of FIGS. 11A-11I following the formation of the gate stack, according to an embodiment of the invention.

FIG. 12C depicts a first top-down view showing where the first and second cross-sectional views of FIGS. 12A and 12B are taken, according to an embodiment of the invention.

FIG. 12D depicts a third cross-sectional view of the semiconductor structure of FIGS. 11A-11I following the formation of the gate stack, according to an embodiment of the invention.

FIG. 12E depicts a fourth cross-sectional view of the semiconductor structure of FIGS. 11A-11I following the formation of the gate stack, according to an embodiment of the invention.

FIG. 12F depicts a fifth cross-sectional view of the semiconductor structure of FIGS. 11A-11I following the formation of the gate stack, according to an embodiment of the invention.

FIG. 12G depicts a second top-down view showing where the third, fourth and fifth cross-sectional views of FIGS. 12D, 12E and 12F are taken, according to an embodiment of the invention.

FIG. 12H depicts a sixth cross-sectional view of the semiconductor structure of FIGS. 11A-11I following the formation of the gate stack, according to an embodiment of the invention.

FIG. 12I depicts a third top-down view showing where the sixth cross-sectional view of FIG. 12H is taken, according to an embodiment of the invention.

FIG. 13A depicts a first cross-sectional view of the semiconductor structure of FIGS. 12A-12I following formation of middle-of-line contacts, frontside back-end-of-line interconnects and bonding to a carrier wafer, according to an embodiment of the invention.

FIG. 13B depicts a second cross-sectional view of the semiconductor structure of FIGS. 12A-12I following the formation of the middle-of-line contacts, the frontside back-end-of-line interconnects and the bonding to the carrier wafer, according to an embodiment of the invention.

FIG. 13C depicts a first top-down view showing where the first and second cross-sectional views of FIGS. 13A and 13B are taken, according to an embodiment of the invention.

FIG. 13D depicts a third cross-sectional view of the semiconductor structure of FIGS. 12A-12I following the formation of the middle-of-line contacts, the frontside back-end-of-line interconnects and the bonding to the carrier wafer, according to an embodiment of the invention.

FIG. 13E depicts a fourth cross-sectional view of the semiconductor structure of FIGS. 12A-12I following the formation of the middle-of-line contacts, the frontside back-end-of-line interconnects and the bonding to the carrier wafer, according to an embodiment of the invention.

FIG. 13F depicts a fifth cross-sectional view of the semiconductor structure of FIGS. 12A-12I following the formation of the middle-of-line contacts, the frontside back-end-of-line interconnects and the bonding to the carrier wafer, according to an embodiment of the invention.

FIG. 13G depicts a second top-down view showing where the third, fourth and fifth cross-sectional views of FIGS. 13D, 13E and 13F are taken, according to an embodiment of the invention.

FIG. 13H depicts a sixth cross-sectional view of the semiconductor structure of FIGS. 12A-12I following the formation of the middle-of-line contacts, the frontside back-end-of-line interconnects and the bonding to the carrier wafer, according to an embodiment of the invention.

FIG. 13I depicts a third top-down view showing where the sixth cross-sectional view of FIG. 13H is taken, according to an embodiment of the invention.

FIG. 14A depicts a first cross-sectional view of the semiconductor structure of FIGS. 13A-13I following a wafer flip and removal of the substrate, according to an embodiment of the invention.

FIG. 14B depicts a second cross-sectional view of the semiconductor structure of FIGS. 13A-13I following the wafer flip and the removal of the substrate, according to an embodiment of the invention.

FIG. 14C depicts a first top-down view showing where the first and second cross-sectional views of FIGS. 14A and 14B are taken, according to an embodiment of the invention.

FIG. 14D depicts a third cross-sectional view of the semiconductor structure of FIGS. 13A-13I following the wafer flip and the removal of the substrate, according to an embodiment of the invention.

FIG. 14E depicts a fourth cross-sectional view of the semiconductor structure of FIGS. 13A-13I following the wafer flip and the removal of the substrate, according to an embodiment of the invention.

FIG. 14F depicts a fifth cross-sectional view of the semiconductor structure of FIGS. 13A-13I following the wafer flip and the removal of the substrate, according to an embodiment of the invention.

FIG. 14G depicts a second top-down view showing where the third, fourth and fifth cross-sectional views of FIGS. 14D, 14E and 14F are taken, according to an embodiment of the invention.

FIG. 14H depicts a sixth cross-sectional view of the semiconductor structure of FIGS. 13A-13I following the wafer flip and the removal of the substrate, according to an embodiment of the invention.

FIG. 14I depicts a third top-down view showing where the sixth cross-sectional view of FIG. 14H is taken, according to an embodiment of the invention.

FIG. 15A depicts a first cross-sectional view of the semiconductor structure of FIGS. 14A-14I following removal of the etch stop layer and the substrate, and following formation of a backside interlayer dielectric layer, according to an embodiment of the invention.

FIG. 15B depicts a second cross-sectional view of the semiconductor structure of FIGS. 14A-14I following the removal of the etch stop layer and the substrate, and following the formation of the backside interlayer dielectric layer, according to an embodiment of the invention.

FIG. 15C depicts a first top-down view showing where the first and second cross-sectional views of FIGS. 15A and 15B are taken, according to an embodiment of the invention.

FIG. 15D depicts a third cross-sectional view of the semiconductor structure of FIGS. 14A-14I following the removal of the etch stop layer and the substrate, and following the formation of the backside interlayer dielectric layer, according to an embodiment of the invention.

FIG. 15E depicts a fourth cross-sectional view of the semiconductor structure of FIGS. 14A-14I following the removal of the etch stop layer and the substrate, and following the formation of the backside interlayer dielectric layer, according to an embodiment of the invention.

FIG. 15F depicts a fifth cross-sectional view of the semiconductor structure of FIGS. 14A-14I following the removal of the etch stop layer and the substrate, and following the formation of the backside interlayer dielectric layer, according to an embodiment of the invention.

FIG. 15G depicts a second top-down view showing where the third, fourth and fifth cross-sectional views of FIGS. 15D, 15E and 15F are taken, according to an embodiment of the invention.

FIG. 15H depicts a sixth cross-sectional view of the semiconductor structure of FIGS. 14A-14I following the removal of the etch stop layer and the substrate, and following the formation of the backside interlayer dielectric layer, according to an embodiment of the invention.

FIG. 15I depicts a third top-down view showing where the sixth cross-sectional view of FIG. 15H is taken, according to an embodiment of the invention.

FIG. 16A depicts a first cross-sectional view of the semiconductor structure of FIGS. 15A-15I following formation of backside power rails, vias and metallization layers, according to an embodiment of the invention.

FIG. 16B depicts a second cross-sectional view of the semiconductor structure of FIGS. 15A-15I following the formation of the backside power rails, vias and metallization layers, according to an embodiment of the invention.

FIG. 16C depicts a first top-down view showing where the first and second cross-sectional views of FIGS. 16A and 16B are taken, according to an embodiment of the invention.

FIG. 16D depicts a third cross-sectional view of the semiconductor structure of FIGS. 15A-15I following the formation of the backside power rails, vias and metallization layers, according to an embodiment of the invention.

FIG. 16E depicts a fourth cross-sectional view of the semiconductor structure of FIGS. 15A-15I following the formation of the backside power rails, vias and metallization layers, according to an embodiment of the invention.

FIG. 16F depicts a fifth cross-sectional view of the semiconductor structure of FIGS. 15A-15I following the formation of the backside power rails, vias and metallization layers, according to an embodiment of the invention.

FIG. 16G depicts a second top-down view showing where the third, fourth and fifth cross-sectional views of FIGS. 16D, 16E and 16F are taken, according to an embodiment of the invention.

FIG. 16H depicts a sixth cross-sectional view of the semiconductor structure of FIGS. 15A-15I following the formation of the backside power rails, vias and metallization layers, according to an embodiment of the invention.

FIG. 16I depicts a seventh cross-sectional view of the semiconductor structure of FIGS. 15A-15I following the formation of the backside power rails, vias and metallization layers, according to an embodiment of the invention.

FIG. 16J depicts a third top-down view showing where the sixth and seventh cross-sectional views of FIGS. 16H and 16I are taken, according to an embodiment of the invention.

FIG. 17A depicts a first cross-sectional view of the semiconductor structure of FIGS. 16A-16J following formation of additional backside power rails, vias and metallization layers, according to an embodiment of the invention.

FIG. 17B depicts a second cross-sectional view of the semiconductor structure of FIGS. 16A-16J following the formation of the additional backside power rails, vias and metallization layers, according to an embodiment of the invention.

FIG. 17C depicts a first top-down view showing where the first and second cross-sectional views of FIGS. 17A and 17B are taken, according to an embodiment of the invention.

FIG. 17D depicts a third cross-sectional view of the semiconductor structure of FIGS. 16A-16J following the formation of the additional backside power rails, vias and metallization layers, according to an embodiment of the invention.

FIG. 17E depicts a fourth cross-sectional view of the semiconductor structure of FIGS. 16A-16J following the formation of the additional backside power rails, vias and metallization layers, according to an embodiment of the invention.

FIG. 17F depicts a fifth cross-sectional view of the semiconductor structure of FIGS. 16A-16J following the formation of the additional backside power rails, vias and metallization layers, according to an embodiment of the invention.

FIG. 17G depicts a second top-down view showing where the third, fourth and fifth cross-sectional views of FIGS. 17D, 17E and 17F are taken, according to an embodiment of the invention.

FIG. 17H depicts a sixth cross-sectional view of the semiconductor structure of FIGS. 16A-16J following the formation of the additional backside power rails, vias and metallization layers, according to an embodiment of the invention.

FIG. 17I depicts a seventh cross-sectional view of the semiconductor structure of FIGS. 16A-16J following the formation of the additional backside power rails, vias and metallization layers, according to an embodiment of the invention.

FIG. 17J depicts a third top-down view showing where the sixth and seventh cross-sectional views of FIGS. 17H and 17I are taken, according to an embodiment of the invention.

FIG. 18A depicts a first cross-sectional view of the semiconductor structure of FIGS. 17A-17J following formation of a backside power delivery network, according to an embodiment of the invention.

FIG. 18B depicts a second cross-sectional view of the semiconductor structure of FIGS. 17A-17J following the formation of the backside power delivery network, according to an embodiment of the invention.

FIG. 18C depicts a first top-down view showing where the first and second cross-sectional views of FIGS. 18A and 18B are taken, according to an embodiment of the invention.

FIG. 18D depicts a third cross-sectional view of the semiconductor structure of FIGS. 17A-17J following the formation of the backside power delivery network, according to an embodiment of the invention.

FIG. 18E depicts a fourth cross-sectional view of the semiconductor structure of FIGS. 17A-17J following the formation of the backside power delivery network, according to an embodiment of the invention.

FIG. 18F depicts a fifth cross-sectional view of the semiconductor structure of FIGS. 17A-17J following the formation of the backside power delivery network, according to an embodiment of the invention.

FIG. 18G depicts a second top-down view showing where the third, fourth and fifth cross-sectional views of FIGS. 18D, 18E and 18F are taken, according to an embodiment of the invention.

FIG. 18H depicts a sixth cross-sectional view of the semiconductor structure of FIGS. 17A-17J following the formation of the backside power delivery network, according to an embodiment of the invention.

FIG. 18I depicts a seventh cross-sectional view of the semiconductor structure of FIGS. 17A-17J following the formation of the backside power delivery network, according to an embodiment of the invention.

FIG. 18J depicts a third top-down view showing where the sixth and seventh cross-sectional views of FIGS. 18H and 18I are taken, according to an embodiment of the invention.

FIGS. 19A and 19B show circuit diagrams for structures with integrated electrostatic discharge clamp circuits, according to an embodiment of the invention.

FIG. 20 shows an integrated circuit comprising one or more semiconductor structures with integrated electrostatic discharge clamp circuits, according to an embodiment of the invention.

### DETAILED DESCRIPTION

Illustrative embodiments of the invention may be described herein in the context of illustrative methods for forming semiconductor structures with integrated electrostatic discharge clamp circuits, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Electrostatic discharge (ESD) presents significant reliability issues in advanced complementary metal-oxide-semiconductor (CMOS) and other semiconductor fabrication technologies. Input/output (I/O)-based ESD protection circuits are inadequate in providing the necessary ESD protection. Therefore, it is important to have an effective ESD power supply clamp across power supply rails so that ESD events will be discharged through the ESD power supply clamp, and thus the ESD power supply clamp protects the circuit core. An ESD power clamp may be provided via a backside power delivery network (BSPDN) process, where passive components (e.g., a resistor (R) and capacitor (C) in an RC-based ESD clamp) are located at the backside of the wafer, with transistors being at the front-end-of-line (FEOL) with connection to the BSPDN through one or more through-silicon vias (TSVs).

Illustrative embodiments provide an approach for integration of an RC-based power rail ESD clamp circuit which eliminates the need for such TSV connections. The RC-based power rail ESD clamp circuit has backside power rails, metal-insulator-metal (MIM) capacitor frontside, and resistor backside scheme that enables the ESD power clamp. Some embodiments also utilize wide nanosheet devices that are enabled through the use of extreme ultraviolet (EUV) lithographic processing techniques, for better discharge capability under ESD stress conditions.

A process flow for forming an RC-based power rail ESD clamp circuit includes forming inverter (e.g., a control circuit) and MIM capacitor (e.g., for an RC-based ESD-transient detection circuit) gate backside vias. Next, an ESD clamp circuit (e.g., a large FET), the inverter and the MIM FEOL formation is performed. Middle-of-line (MOL) contacts and via-to-buried power rail (VBPR) formation is then performed, followed by frontside back-end-of-line (BEOL) formation and carrier wafer bonding. A wafer flip is performed, followed by backside substrate removal, etch stop layer removal, and removal of a remaining semiconductor layer (e.g., silicon). Backside interlayer dielectric (ILD) deposition and chemical mechanical planarization (CMP) are performed, followed by additional backside ILD deposition and backside via formation. A backside resistor (e.g., for the RC-based ESD-transient detection circuit) is then formed. The rest of a BSPDN is then formed.

In some embodiments, a semiconductor device comprises an RC-based power rail ESD clamp circuit, including an ESD clamp device (e.g., a transistor), a control circuit (e.g., an inverter), and passive devices (e.g., an RC-based ESD-transient detection circuit). Source/drain regions of the transistor of the ESD clamp device are connected to ground (e.g., Vss) and positive supply voltage (Vdd) power rails through vias for backside buried power rails (BPRs) (e.g., VPBR structures). The transistor is connected in in parallel between the Vss and Vdd power rails, and is configured to provide a current path during ESD events. Source/drain regions of the inverter are also connected to the Vss and Vdd power rails through VBPR structures. The passive devices may include an MIM capacitor and a resistor. The MIM capacitor may be located at FEOL with a top electrode connected to the backside Vss power rail through a VBPR structure, and with a bottom electrode connected to a first surface of the resistor through a gate backside via and backside interconnects. The resistor is located at or in the BSPDN, with the second surface of the resistor being connected to the Vdd power rail through the BSPDN. The backside interconnects are connected to an input of the inverter through a gate backside via that extends to shallow trench isolation (STI) regions. The output of the inverter is connected to the input of the transistor of the ESD clamp device through wafer frontside BEOL interconnects.

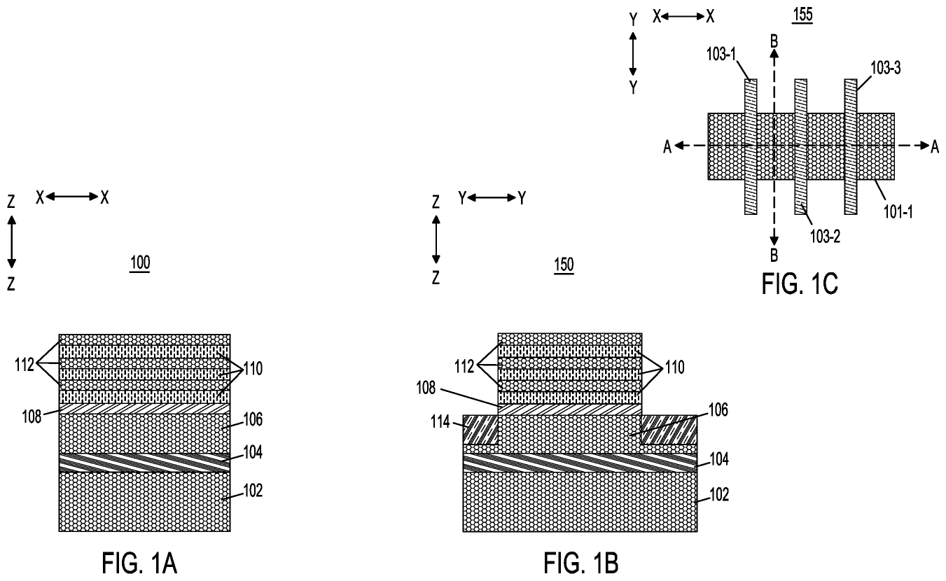

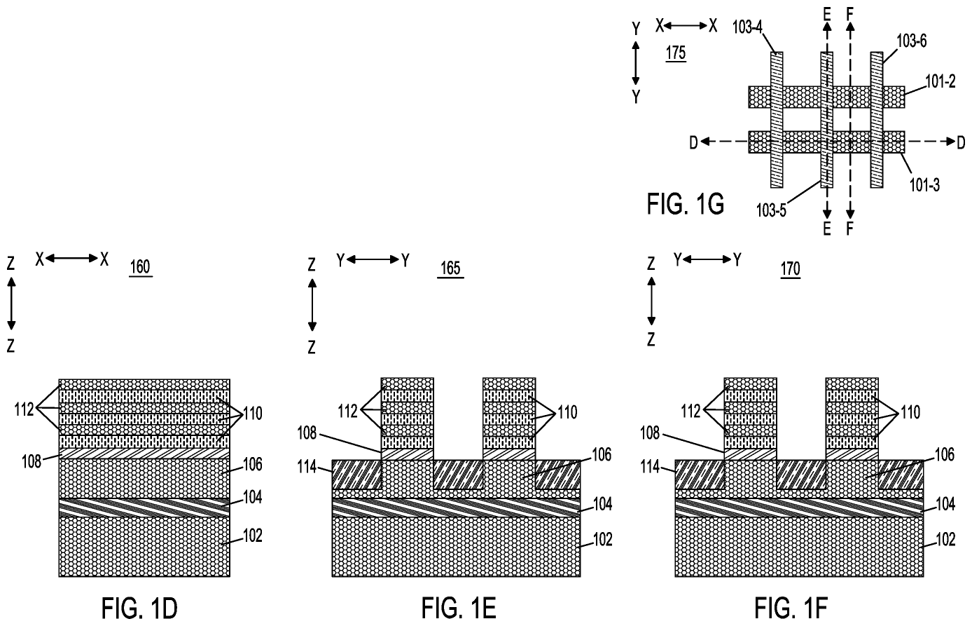

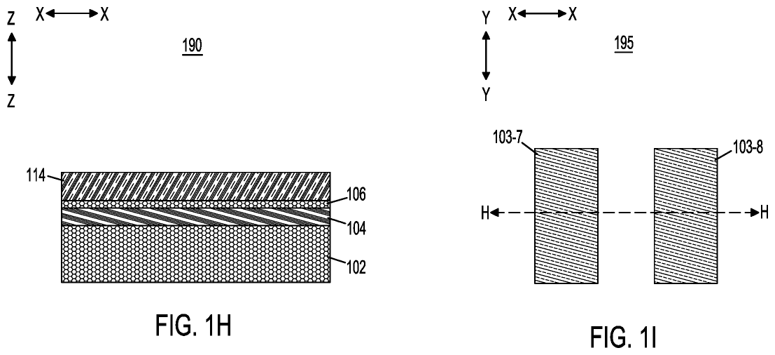

FIGS. 1A-18J show a process flow for forming semiconductor structures with integrated electrostatic discharge (ESD) clamping circuits.

FIGS. 1A-1I show different views of a semiconductor structure following patterning of a nanosheet stack and formation of STI regions. FIGS. 1A and 1B show respective cross-sectional views 100 and 150 of a high current capacity transistor (e.g., an ESD clamp device) region of the semiconductor structure, with FIG. 1C showing a top-down view 155 illustrating where the cross-sectional views 100 and 150 are taken in the high current capacity transistor region of the semiconductor structure. FIG. 1C shows a fin active region 101-1 for the high current capacity transistor, along with gate regions 103-1, 103-2 and 103-3 for the high current capacity transistor. The cross-sectional view 100 of FIG. 1A is taken along the line A-A in the top-down view 155 of FIG. 1C (e.g., along the fin active region 101-1), and the cross-sectional view 150 of FIG. 1B is taken along the line B-B in the top-down view 155 of FIG. 1C (e.g., across the gate regions 103-1, 103-2 and 103-3). FIGS. 1D, 1E and 1F show respective cross-sectional views 160, 165 and 170 of a control circuit (e.g., inverter) region of the semiconductor structure, with FIG. 1G showing a top-down view 175 illustrating where the cross-sectional views 160, 165 and 170 are taken in the control circuit region of the semiconductor structure. FIG. 1G shows fin active regions 101-2 and 101-3 for the control circuit (e.g., the inverter), along with gate regions 103-4, 103-5 and 103-6 for the control circuit (e.g., the inverter). The fin active region 101-2 may be for an p-type field-effect transistor (PFET) of the inverter, while the fin active region 101-3 may be for an n-type field-effect transistor (NFET) of the inverter, or vice-versa. The cross-sectional view 160 of FIG. 1D is taken along the line D-D in the top-down view 175 of FIG. 1G (e.g., along the fin active region 101-3), the cross-sectional view 165 of FIG. 1E is taken along the line E-E in the top-down view 175 of FIG. 1G (e.g., along the gate region 103-5), and the cross-sectional view 170 of FIG. 1F is taken along the line F-F in the top-down view 175 of FIG. 1G (e.g., between the gate regions 103-5 and 103-6 across the fin active regions 101-2 and 101-3). FIG. 1H shows a cross-sectional view 190 of an ESD-transient detection circuit (e.g., RC passive devices, including a frontside capacitor) region of the semiconductor structure, with FIG. 1I showing a top-down view 195 illustrating where the cross-sectional view 190 is taken in the ESD-transient detection circuit region of the semiconductor structure. FIG. 1I shows dummy gate regions 103-7 and 103-8 for the ESD-transient detection circuit. The cross-sectional view 190 of FIG. 1H is taken along the line H-H in the top-down view 195 of FIG. 1I (e.g., across the dummy gate regions 103-7 and 103-8).

As shown in FIGS. 1A-1I, the semiconductor structure includes a substrate 102, an etch stop layer 104, a semiconductor layer 106, a sacrificial layer 108, sacrificial layers 110, nanosheet channel layers 112, and STI regions 114.

The substrate 102 and the semiconductor layer 106 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. The substrate 102 and the semiconductor layer 106 may have respective heights (in direction Z) and widths (in directions X/Y) which vary as needed based on the type of structures to be formed.

The etch stop layer 104 may comprise a buried oxide (BOX) layer formed of silicon dioxide (SiO₂), silicon germanium (SiGe), or another suitable material such as a III-V semiconductor epitaxial layer. The etch stop layer 104 may have a height (in direction Z) in the range of 10 to 30 nm.

The sacrificial layer 108 may be formed of a first sacrificial material and the sacrificial layers 110 may be formed of a second sacrificial material different than the first sacrificial material, such that the sacrificial layer 108 may be etched or otherwise removed selective to the sacrificial layers 110. In some embodiments, both the sacrificial layer 108 and the sacrificial layers 110 are formed of SiGe, but with different percentages of Ge. For example, the sacrificial layer 108 may have a relatively higher percentage of Ge (e.g., 60% Ge), and the sacrificial layers 110 may have a relatively lower percentage of Ge (e.g., 30% Ge). Other combinations of different sacrificial materials may be used in other embodiments. The sacrificial layer 108 and the sacrificial layers 110 may each have a thickness (in direction Z) in the range of 6-15 nm.

The nanosheet channel layers 112 will provide channels for different transistor structures (e.g., nanosheet transistors). For example, the portions of the nanosheet channel layers 112 shown in FIGS. 1A and 1B provide channel layers for the high current capacity transistor, while the portions of the nanosheet channel layers 112 shown in FIGS. 1D, 1E and 1F provide channel layers for PFET and NFET transistors forming an inverter for the control circuit. The nanosheet channel layers 112 may be formed of Si or another suitable material (e.g., a material similar to that used for the substrate 102 and the semiconductor layer 106). Each of the nanosheet channel layers 112 may have a thickness (in direction Z) in the range of 4-10 nm.

The STI regions 114 are formed by patterning a mask layer over the nanosheet stack, and then etching exposed portions of the nanosheet stack and into the semiconductor layer 106, followed by deposition or other formation of material for the STI regions 114. The STI regions 114 may be formed of a dielectric material such as silicon dioxide (SiO₂), silicon oxycarbide (SiOC), silicon oxynitride (SiON), etc. The STI regions 114 may have a height (in direction Z) in the range of 20 to 100 nm.

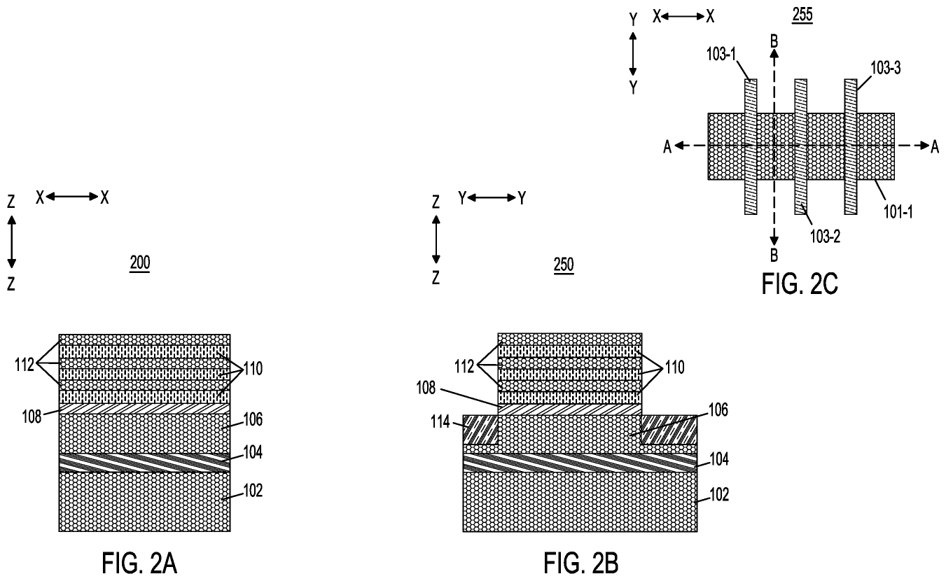

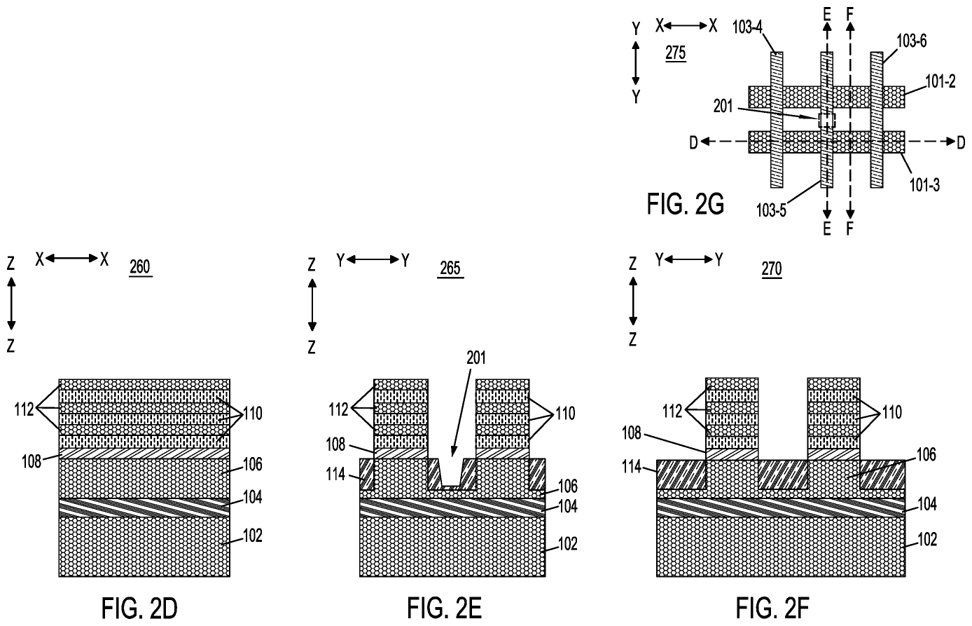

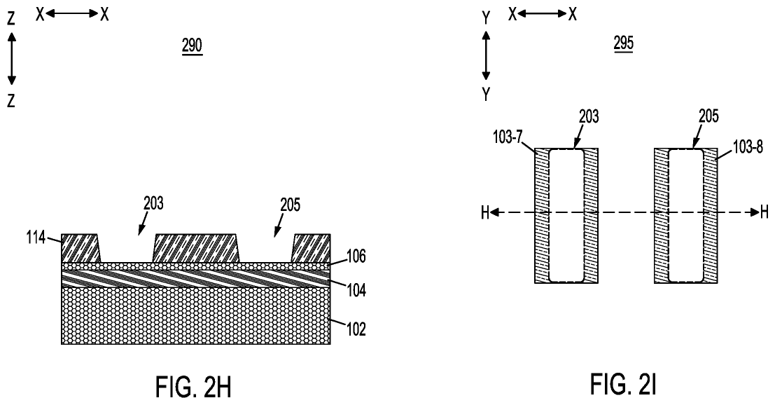

FIGS. 2A-2I show different views of the semiconductor structure of FIGS. 1A-1I following gate backside via patterning. FIGS. 2A and 2B show respective cross-sectional views 200 and 250 of the high current capacity transistor region of the semiconductor structure, with FIG. 2C showing a top-down view 255 illustrating where the cross-sectional views 200 and 250 are taken in the high current capacity transistor region of the semiconductor structure. The cross-sectional view 200 of FIG. 2A is taken along the line A-A in the top-down view 255 of FIG. 2C (e.g., along the fin active region 101-1), and the cross-sectional view 250 of FIG. 2B is taken along the line B-B in the top-down view 255 of FIG. 2C (e.g., across the gate regions 103-1, 103-2 and 103-3). FIGS. 2D, 2E and 2F show respective cross-sectional views 260, 265 and 270 of the control circuit region of the semiconductor structure, with FIG. 2G showing a top-down view 275 illustrating where the cross-sectional views 260, 265 and 270 are taken in the control circuit region of the semiconductor structure. The cross-sectional view 260 of FIG. 2D is taken along the line D-D in the top-down view 275 of FIG. 2G (e.g., along the fin active region 101-3), the cross-sectional view 265 of FIG. 2E is taken along the line E-E in the top-down view 275 of FIG. 2G (e.g., along the gate region 103-5), and the cross-sectional view 270 of FIG. 2F is taken along the line F-F in the top-down view 275 of FIG. 2G (e.g., between the gate regions 103-5 and 103-6 across the fin active regions 101-2 and 101-3). FIG. 2H shows a cross-sectional view 290 of the ESD-transient detection circuit region of the semiconductor structure, with FIG. 2I showing a top-down view 295 illustrating where the cross-sectional view 290 is taken in the ESD-transient detection circuit region of the semiconductor structure. The cross-sectional view 290 of FIG. 2H is taken along the line H-H in the top-down view 295 of FIG. 2I (e.g., across the dummy gate regions 103-7 and 103-8).

The gate backside via patterning includes patterning a mask layer over the structure, and then etching exposed portions of the STI regions 114 in areas where gate backside vias are to be formed. This includes a first gate backside via 201 between the fin active regions 101-2 and 101-3 in the control circuit region as shown in FIGS. 2E and 2G, along with gate backside vias 203 and 205 in the ESD-transient detection circuit region as shown in FIGS. 2H and 2I.

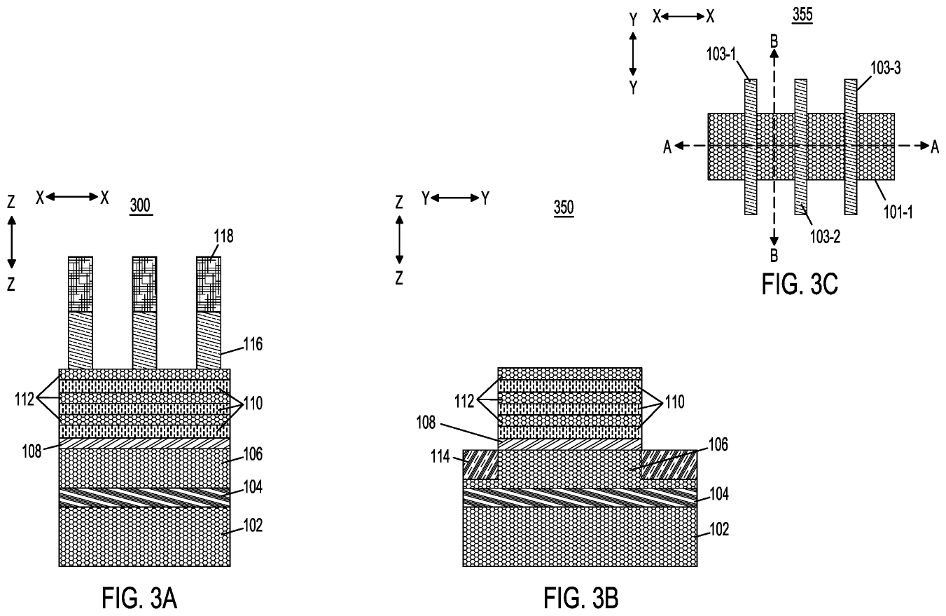

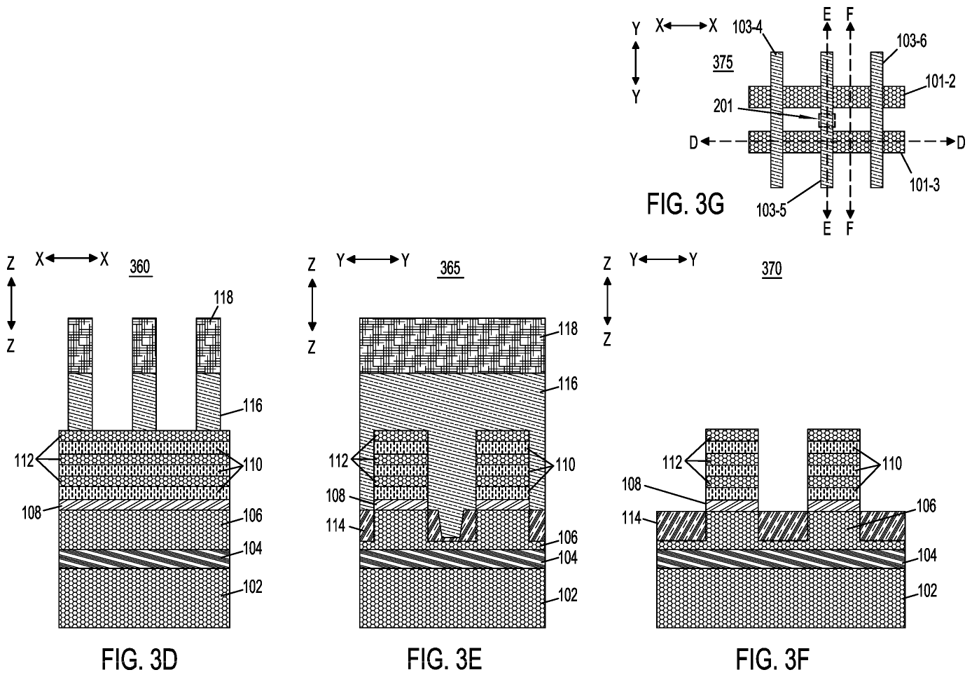

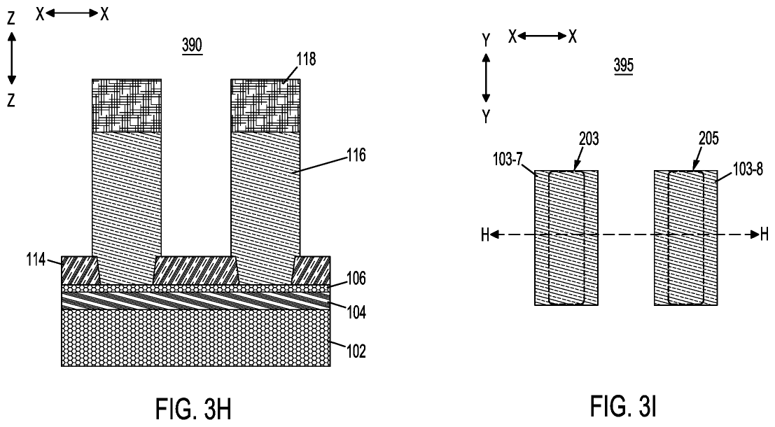

FIGS. 3A-3I show different views of the semiconductor structure of FIGS. 2A-2I following dummy gate patterning. FIGS. 3A and 3B show respective cross-sectional views 300 and 350 of the high current capacity transistor region of the semiconductor structure, with FIG. 3C showing a top-down view 355 illustrating where the cross-sectional views 300 and 350 are taken in the high current capacity transistor region of the semiconductor structure. The cross-sectional view 300 of FIG. 3A is taken along the line A-A in the top-down view 355 of FIG. 3C (e.g., along the fin active region 101-1), and the cross-sectional view 350 of FIG. 3B is taken along the line B-B in the top-down view 355 of FIG. 3C (e.g., across the gate regions 103-1, 103-2 and 103-3). FIGS. 3D, 3E and 3F show respective cross-sectional views 360, 365 and 370 of the control circuit region of the semiconductor structure, with FIG. 3G showing a top-down view 375 illustrating where the cross-sectional views 360, 365 and 370 are taken in the control circuit region of the semiconductor structure. The cross-sectional view 360 of FIG. 3D is taken along the line D-D in the top-down view 375 of FIG. 3G (e.g., along the fin active region 101-3), the cross-sectional view 365 of FIG. 3E is taken along the line E-E in the top-down view 375 of FIG. 3G (e.g., along the gate region 103-5), and the cross-sectional view 370 of FIG. 3F is taken along the line F-F in the top-down view 375 of FIG. 3G (e.g., between the gate regions 103-5 and 103-6 across the fin active regions 101-2 and 101-3). FIG. 3H shows a cross-sectional view 390 of the ESD-transient detection circuit region of the semiconductor structure, with FIG. 3I showing a top-down view 395 illustrating where the cross-sectional view 390 is taken in the ESD-transient detection circuit region of the semiconductor structure. The cross-sectional view 390 of FIG. 3H is taken along the line H-H in the top-down view 395 of FIG. 3I (e.g., across the dummy gate regions 103-7 and 103-8).

The dummy gate patterning includes formation of dummy gate structures including dummy gate layers 116 and gate hard mask (HM) layers 118. Material for the dummy gate layers 116 (e.g., amorphous silicon (a-Si), amorphous silicon germanium (a-SiGe) over a thin SiO₂ or titanium nitride (TiN) layer, or another suitable material) may be blanket deposited over the structure, followed by formation and patterning of the gate HM layers 118 (e.g., formed of silicon nitride (SiN), a multi-layer of SiN and SiO₂, or another suitable material), followed by lithographic processing to result in the dummy gate layers 116 and gate HM layers 118 as shown in FIGS. 3A-3I. The dummy gate layers 116 may each have a width (in direction X) in the range of 10-100 nm. The gate HM layers 118 may have a height (in direction Z) in the range of 10 nm or larger, and a width (in direction X) that matches that of the underlying dummy gate layers 116.

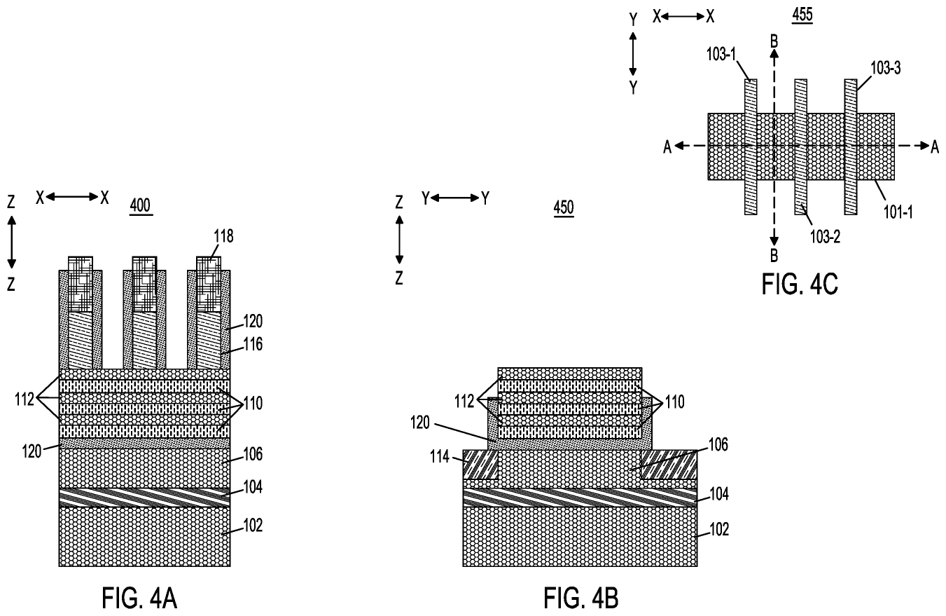

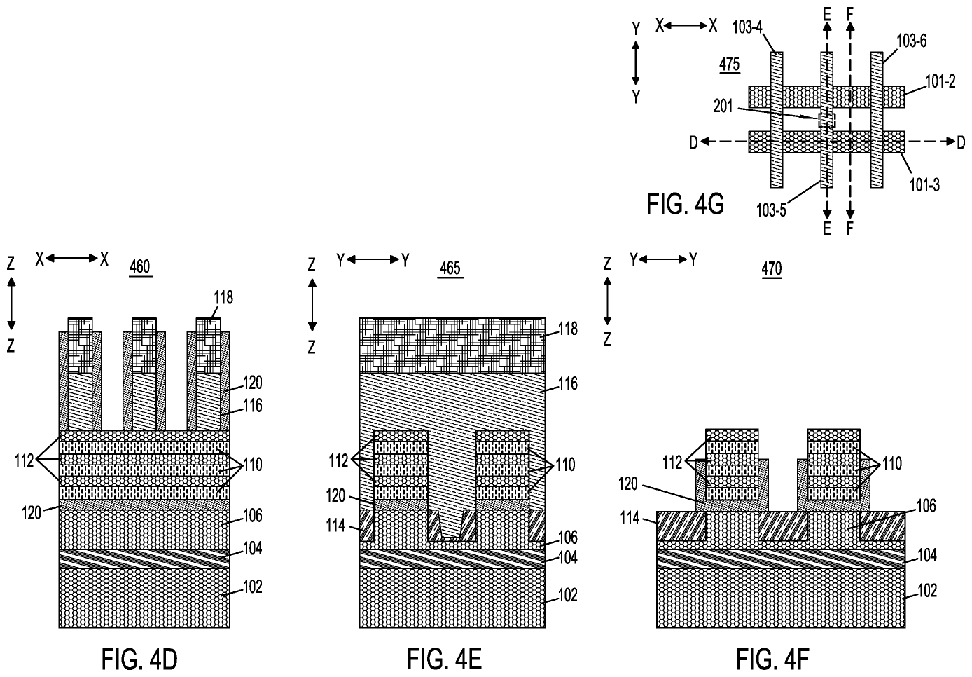

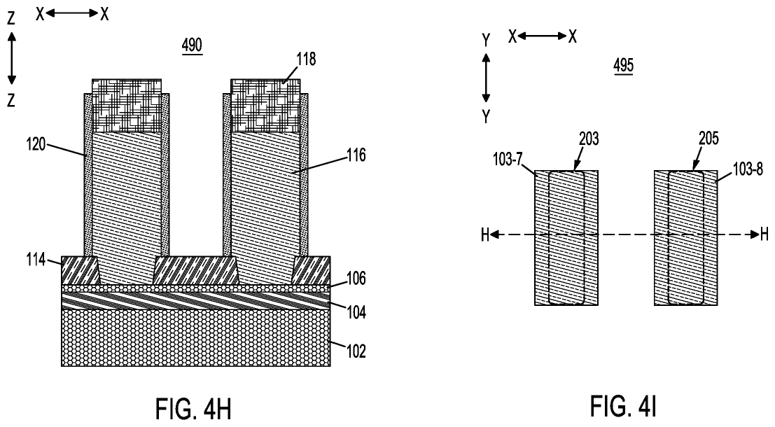

FIGS. 4A-4I show different views of the semiconductor structure of FIGS. 3A-3I following removal of the sacrificial layer 108 and formation of spacer material. FIGS. 4A and 4B show respective cross-sectional views 400 and 450 of the high current capacity transistor region of the semiconductor structure, with FIG. 4C showing a top-down view 455 illustrating where the cross-sectional views 400 and 450 are taken in the high current capacity transistor region of the semiconductor structure. The cross-sectional view 400 of FIG. 4A is taken along the line A-A in the top-down view 455 of FIG. 4C (e.g., along the fin active region 101-1), and the cross-sectional view 450 of FIG. 4B is taken along the line B-B in the top-down view 455 of FIG. 4C (e.g., across the gate regions 103-1, 103-2 and 103-3). FIGS. 4D, 4E and 4F show respective cross-sectional views 460, 465 and 470 of the control circuit region of the semiconductor structure, with FIG. 4G showing a top-down view 475 illustrating where the cross-sectional views 460, 465 and 470 are taken in the control circuit region of the semiconductor structure. The cross-sectional view 460 of FIG. 4D is taken along the line D-D in the top-down view 475 of FIG. 4G (e.g., along the fin active region 101-3), the cross-sectional view 465 of FIG. 4E is taken along the line E-E in the top-down view 475 of FIG. 4G (e.g., along the gate region 103-5), and the cross-sectional view 470 of FIG. 4F is taken along the line F-F in the top-down view 475 of FIG. 4G (e.g., between the gate regions 103-5 and 103-6 across the fin active regions 101-2 and 101-3). FIG. 4H shows a cross-sectional view 490 of the ESD-transient detection circuit region of the semiconductor structure, with FIG. 4I showing a top-down view 495 illustrating where the cross-sectional view 490 is taken in the ESD-transient detection circuit region of the semiconductor structure. The cross-sectional view 490 of FIG. 4H is taken along the line H-H in the top-down view 495 of FIG. 4I (e.g., across the dummy gate regions 103-7 and 103-8).

The sacrificial layer 108 may be removed (e.g., selective to the sacrificial layers 110), followed by deposition and etching (e.g., using reactive-ion etching (RIE) or other suitable processing) of spacer material. The spacer material provides a spacer layer 120. In the space between the semiconductor layer 106 and the bottom-most one of the sacrificial layers 110, the spacer layer 120 acts a bottom dielectric insulator (BDI) or self-aligned silicon insulator (SASI). The portions of the spacer layer 120 on sidewalls of the dummy gate layers 116 and the gate HM layers 118 provide gate sidewall spacers. The spacer layer 120 may be formed of a lower-k conformal dielectric film such as silicon boron carbon nitride (SiBCN), silicon oxygen carbon nitride (SiOCN), silicon oxygen carbide (SiOC), silicon oxygen carbon nitride (SiOCN), etc. The spacer layer 120 may have a thickness in the range of 5-10 nm.

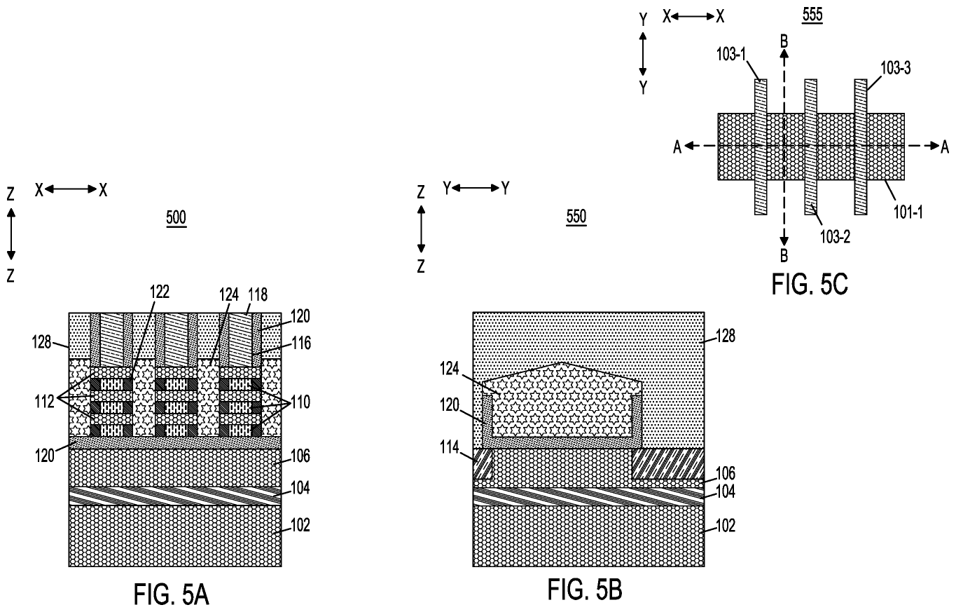

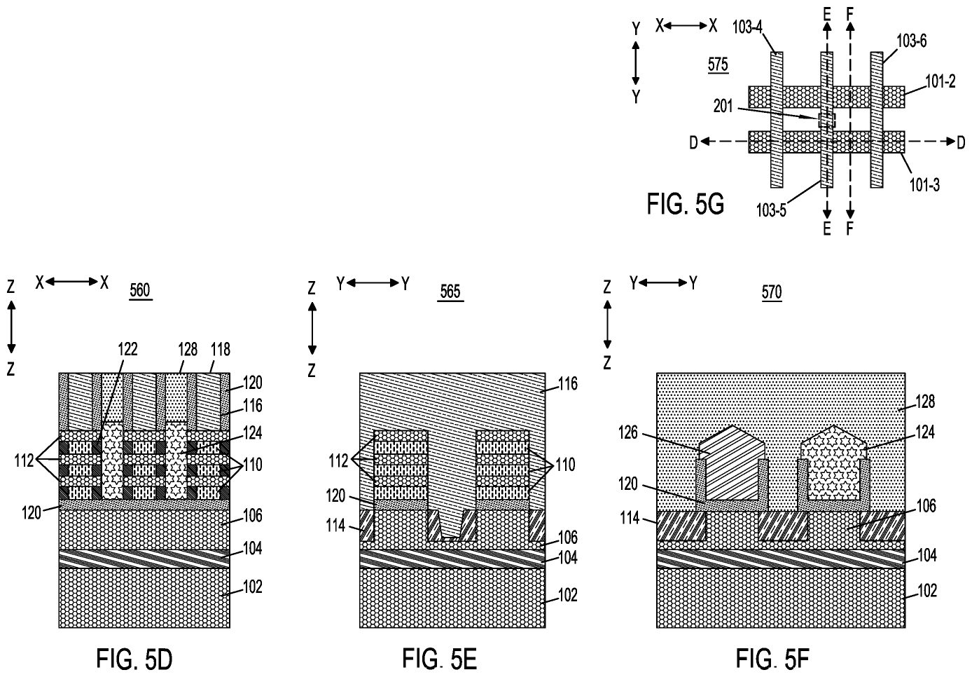

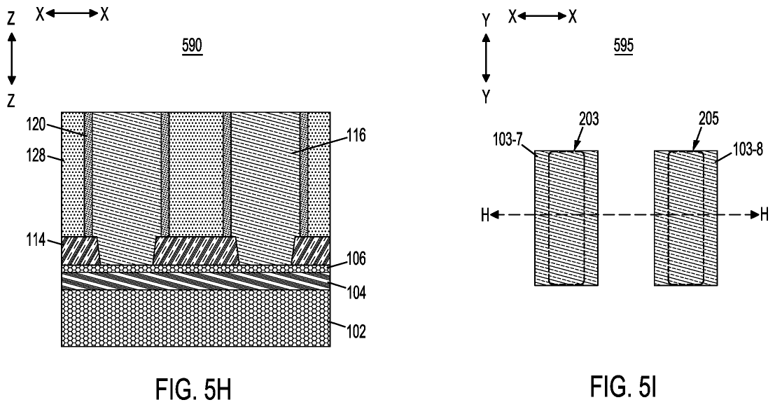

FIGS. 5A-5I show different views of the semiconductor structure of FIGS. 4A-4I following recess of the sacrificial layers 110, formation of inner spacers 122, formation of source/drain regions 124 and 126, and formation of a frontside ILD layer 128. FIGS. 5A and 5B show respective cross-sectional views 500 and 550 of the high current capacity transistor region of the semiconductor structure, with FIG. 5C showing a top-down view 555 illustrating where the cross-sectional views 500 and 550 are taken in the high current capacity transistor region of the semiconductor structure. The cross-sectional view 500 of FIG. 5A is taken along the line A-A in the top-down view 555 of FIG. 5C (e.g., along the fin active region 101-1), and the cross-sectional view 550 of FIG. 5B is taken along the line B-B in the top-down view 555 of FIG. 5C (e.g., across the gate regions 103-1, 103-2 and 103-3). FIGS. 5D, 5E and 5F show respective cross-sectional views 560, 565 and 570 of the control circuit region of the semiconductor structure, with FIG. 5G showing a top-down view 575 illustrating where the cross-sectional views 560, 565 and 570 are taken in the control circuit region of the semiconductor structure. The cross-sectional view 560 of FIG. 5D is taken along the line D-D in the top-down view 575 of FIG. 5G (e.g., along the fin active region 101-3), the cross-sectional view 565 of FIG. 5E is taken along the line E-E in the top-down view 575 of FIG. 5G (e.g., along the gate region 103-5), and the cross-sectional view 570 of FIG. 5F is taken along the line F-F in the top-down view 575 of FIG. 5G (e.g., between the gate regions 103-5 and 103-6 across the fin active regions 101-2 and 101-3). FIG. 5H shows a cross-sectional view 590 of the ESD-transient detection circuit region of the semiconductor structure, with FIG. 5I showing a top-down view 595 illustrating where the cross-sectional view 590 is taken in the ESD-transient detection circuit region of the semiconductor structure. The cross-sectional view 590 of FIG. 5H is taken along the line H-H in the top-down view 595 of FIG. 5I (e.g., across the dummy gate regions 103-7 and 103-8).

Nanosheet recess of the nanosheet stack may be performed utilizing RIE or other suitable processing which removes portions of the nanosheet stack which are exposed by the gate HM layers 118 and spacer layer 120. An indent etch may then be performed to indent the sacrificial layers 110. The depth of the indent etch (in direction X) may be in the range of 5-9 nm. Spacer material for the inner spacers 122 is then formed and patterned. This spacer material may be SiN, SiBCN, SiOCN, SiC, SiOC, etc.

The source/drain regions 124 and 126 are formed over the spacer layer 120 between the nanosheet channel layers 112. The source/drain regions 124 and 126 may be formed using an epitaxial growth process. The source/drain regions 124 and 126 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI). The source/drain regions 124 and 126 may be formed by an epitaxial growth process. In some embodiments, the epitaxy process comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×1020 cm⁻³ to 3×10²¹ cm⁻³.

The frontside ILD layer 128 is formed over the source/drain regions 124 and 126 surrounding the dummy gate structures. The frontside ILD layer 128 may be formed of any suitable isolating material, such as SiO₂, SiOC, SiON, etc.

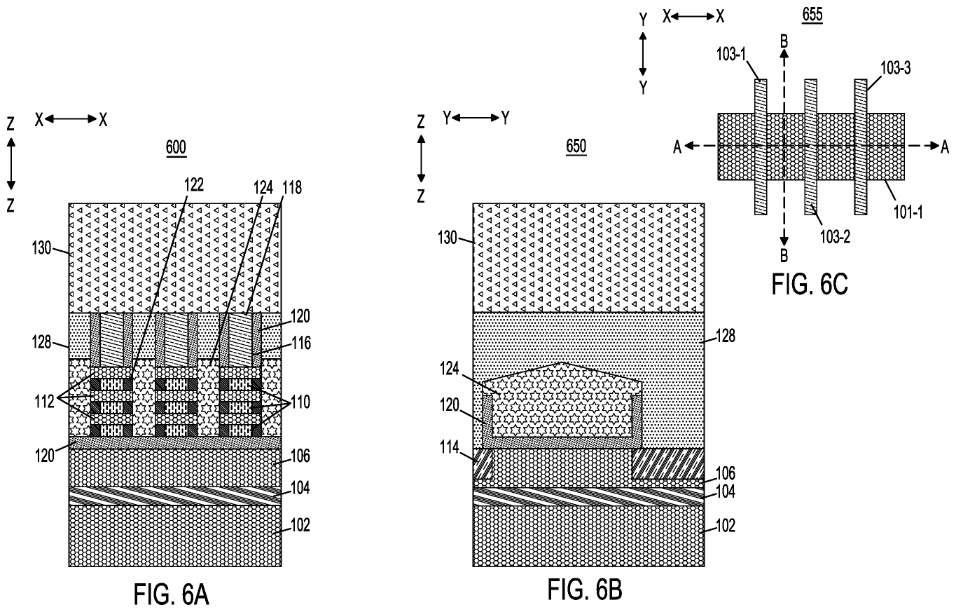

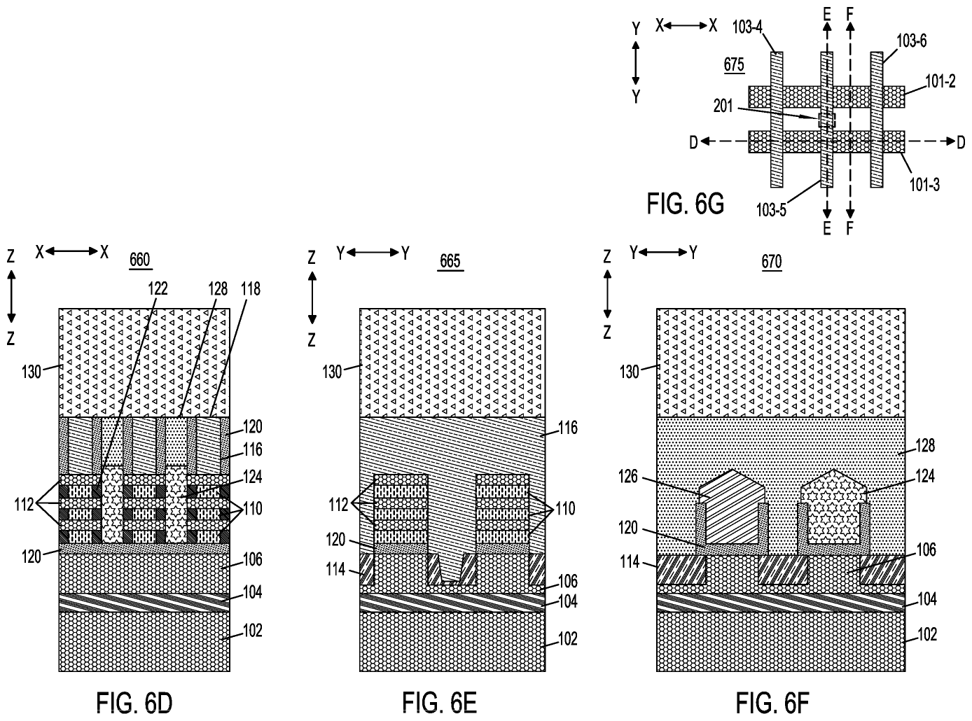

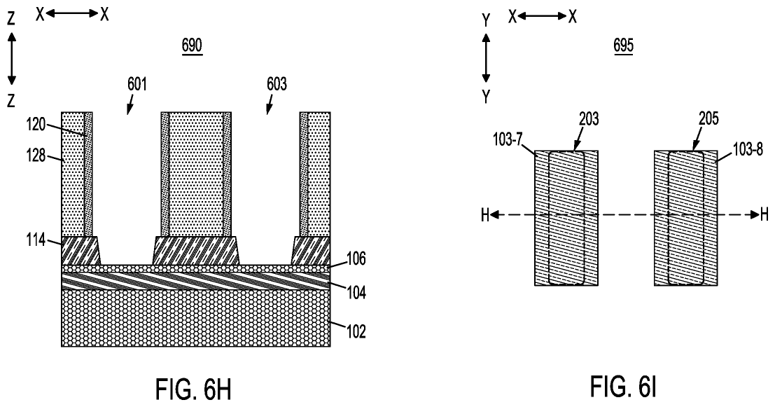

FIGS. 6A-6I show different views of the semiconductor structure of FIGS. 5A-5I following removal of the dummy gate layers 116 and patterning of a MIM region. FIGS. 6A and 6B show respective cross-sectional views 600 and 650 of the high current capacity transistor region of the semiconductor structure, with FIG. 6C showing a top-down view 655 illustrating where the cross-sectional views 600 and 650 are taken in the high current capacity transistor region of the semiconductor structure. The cross-sectional view 600 of FIG. 6A is taken along the line A-A in the top-down view 655 of FIG. 6C (e.g., along the fin active region 101-1), and the cross-sectional view 650 of FIG. 6B is taken along the line B-B in the top-down view 655 of FIG. 6C (e.g., across the gate regions 103-1, 103-2 and 103-3). FIGS. 6D, 6E and 6F show respective cross-sectional views 660, 665 and 670 of the control circuit region of the semiconductor structure, with FIG. 6G showing a top-down view 675 illustrating where the cross-sectional views 660, 665 and 670 are taken in the control circuit region of the semiconductor structure. The cross-sectional view 660 of FIG. 6D is taken along the line D-D in the top-down view 675 of FIG. 6G (e.g., along the fin active region 101-3), the cross-sectional view 665 of FIG. 6E is taken along the line E-E in the top-down view 675 of FIG. 6G (e.g., along the gate region 103-5), and the cross-sectional view 670 of FIG. 6F is taken along the line F-F in the top-down view 675 of FIG. 6G (e.g., between the gate regions 103-5 and 103-6 across the fin active regions 101-2 and 101-3). FIG. 6H shows a cross-sectional view 690 of the ESD-transient detection circuit region of the semiconductor structure, with FIG. 6I showing a top-down view 695 illustrating where the cross-sectional view 690 is taken in the ESD-transient detection circuit region of the semiconductor structure. The cross-sectional view 690 of FIG. 6H is taken along the line H-H in the top-down view 695 of FIG. 6I (e.g., across the dummy gate regions 103-7 and 103-8).

As shown in FIGS. 6A-6I, lithographic layers 130 are patterned over the structure exposing the ESD-transient detection circuit region. The dummy gate layers 116 are then removed from the EDS-transient detection circuit region as shown in FIG. 6H. This results in patterning of MIM regions 601 and 603 in the ESD-transient detection circuit region.

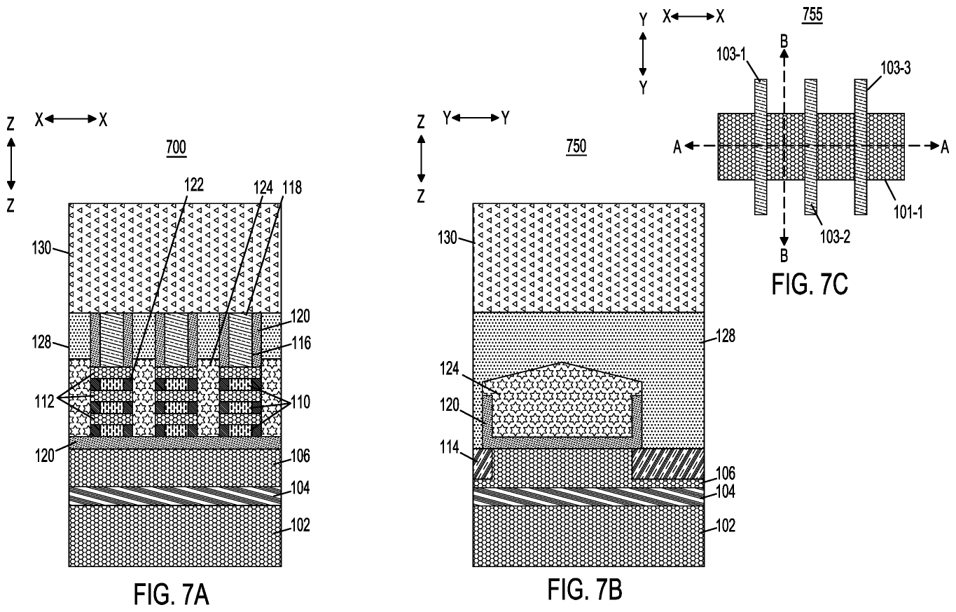

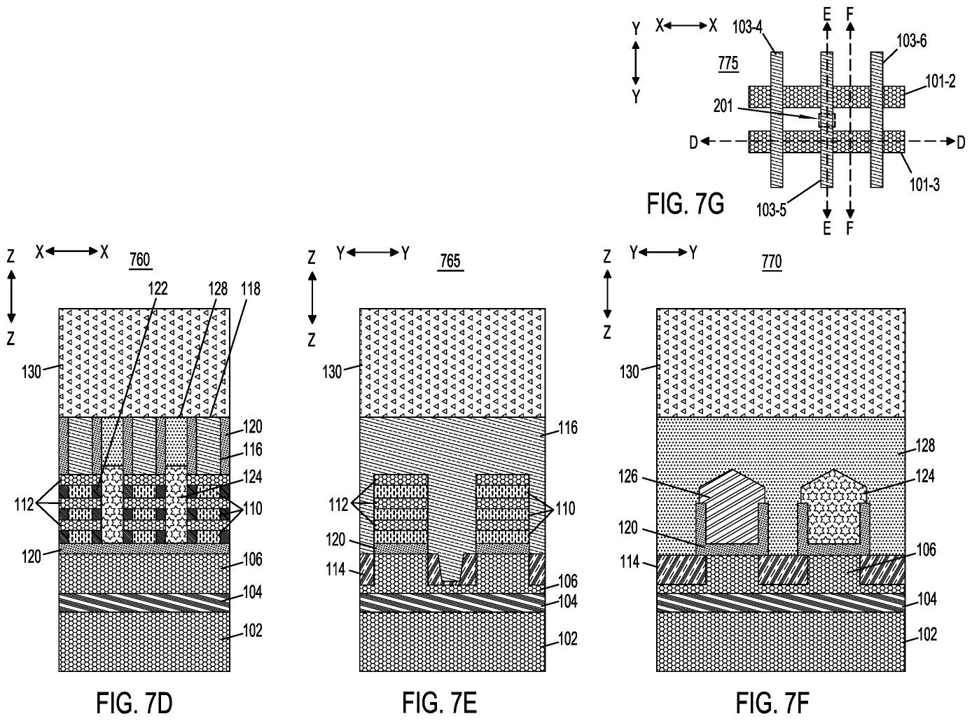

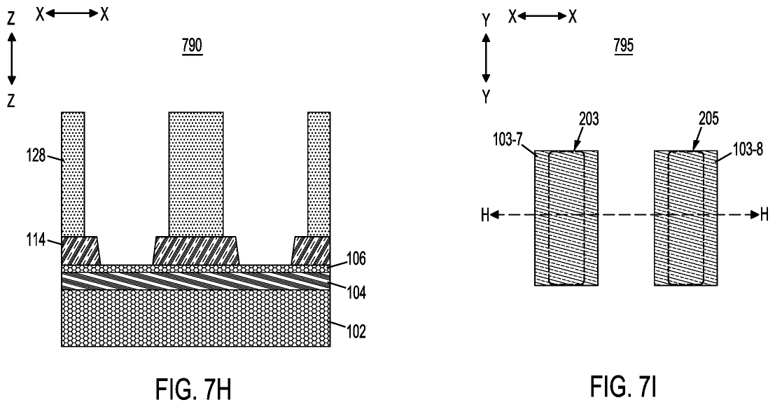

FIGS. 7A-7I show different views of the semiconductor structure of FIGS. 6A-6I following removal of the spacer layer 120 from the MIM region. FIGS. 7A and 7B show respective cross-sectional views 700 and 750 of the high current capacity transistor region of the semiconductor structure, with FIG. 7C showing a top-down view 755 illustrating where the cross-sectional views 700 and 750 are taken in the high current capacity transistor region of the semiconductor structure. The cross-sectional view 700 of FIG. 7A is taken along the line A-A in the top-down view 755 of FIG. 7C (e.g., along the fin active region 101-1), and the cross-sectional view 750 of FIG. 7B is taken along the line B-B in the top-down view 755 of FIG. 7C (e.g., across the gate regions 103-1, 103-2 and 103-3). FIGS. 7D, 7E and 7F show respective cross-sectional views 760, 765 and 770 of the control circuit region of the semiconductor structure, with FIG. 7G showing a top-down view 775 illustrating where the cross-sectional views 760, 765 and 770 are taken in the control circuit region of the semiconductor structure. The cross-sectional view 760 of FIG. 7D is taken along the line D-D in the top-down view 775 of FIG. 7G (e.g., along the fin active region 101-3), the cross-sectional view 765 of FIG. 7E is taken along the line E-E in the top-down view 775 of FIG. 7G (e.g., along the gate region 103-5), and the cross-sectional view 770 of FIG. 7F is taken along the line F-F in the top-down view 775 of FIG. 7G (e.g., between the gate regions 103-5 and 103-6 across the fin active regions 101-2 and 101-3). FIG. 7H shows a cross-sectional view 790 of the ESD-transient detection circuit region of the semiconductor structure, with FIG. 7I showing a top-down view 795 illustrating where the cross-sectional view 790 is taken in the ESD-transient detection circuit region of the semiconductor structure. The cross-sectional view 790 of FIG. 7H is taken along the line H-H in the top-down view 795 of FIG. 7I (e.g., across the dummy gate regions 103-7 and 103-8). In the ESD-transient detection circuit region, the spacer layer 120 is removed as shown in FIG. 7H.

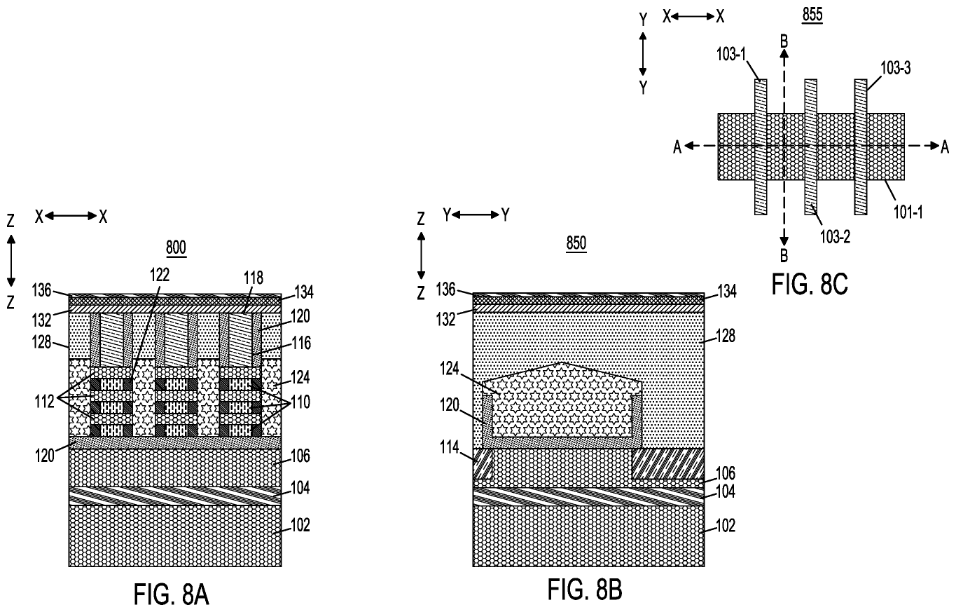

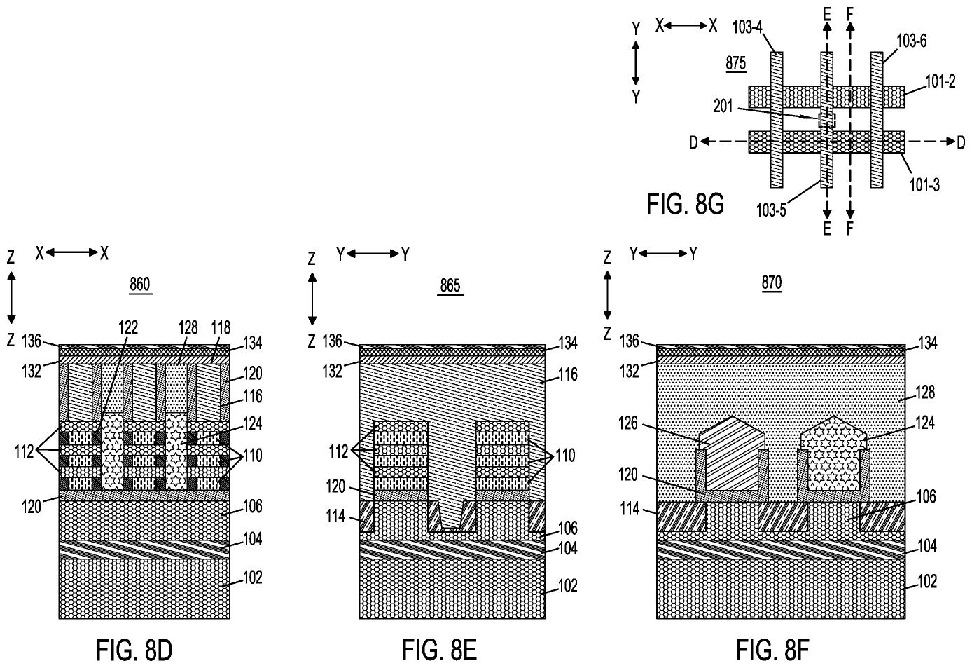

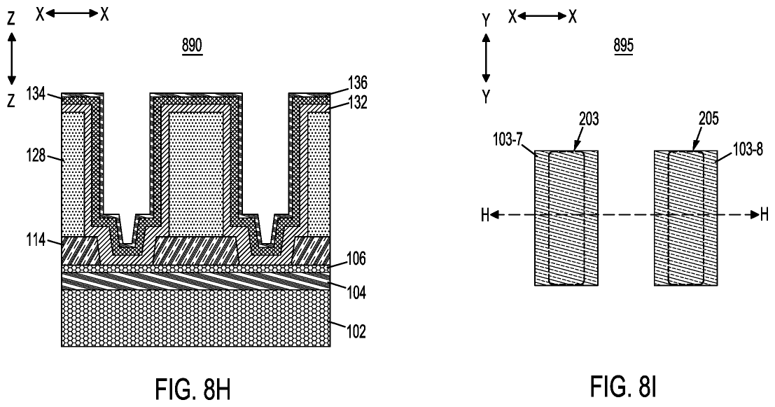

FIGS. 8A-8I show different views of the semiconductor structure of FIGS. 7A-7I following formation of a bottom electrode layer 132 for a capacitor, a dielectric layer 134 and a capping liner layer 136. FIGS. 8A and 8B show respective cross-sectional views 800 and 850 of the high current capacity transistor region of the semiconductor structure, with FIG. 8C showing a top-down view 855 illustrating where the cross-sectional views 800 and 850 are taken in the high current capacity transistor region of the semiconductor structure. The cross-sectional view 800 of FIG. 8A is taken along the line A-A in the top-down view 855 of FIG. 8C (e.g., along the fin active region 101-1), and the cross-sectional view 850 of FIG. 8B is taken along the line B-B in the top-down view 855 of FIG. 8C (e.g., across the gate regions 103-1, 103-2 and 103-3). FIGS. 8D, 8E and 8F show respective cross-sectional views 860, 865 and 870 of the control circuit region of the semiconductor structure, with FIG. 8G showing a top-down view 875 illustrating where the cross-sectional views 860, 865 and 870 are taken in the control circuit region of the semiconductor structure. The cross-sectional view 860 of FIG. 8D is taken along the line D-D in the top-down view 875 of FIG. 8G (e.g., along the fin active region 101-3), the cross-sectional view 865 of FIG. 8E is taken along the line E-E in the top-down view 875 of FIG. 8G (e.g., along the gate region 103-5), and the cross-sectional view 870 of FIG. 8F is taken along the line F-F in the top-down view 875 of FIG. 8G (e.g., between the gate regions 103-5 and 103-6 across the fin active regions 101-2 and 101-3). FIG. 8H shows a cross-sectional view 890 of the ESD-transient detection circuit region of the semiconductor structure, with FIG. 8I showing a top-down view 895 illustrating where the cross-sectional view 890 is taken in the ESD-transient detection circuit region of the semiconductor structure. The cross-sectional view 890 of FIG. 8H is taken along the line H-H in the top-down view 895 of FIG. 8I (e.g., across the dummy gate regions 103-7 and 103-8).

The lithographic layers 130 are removed, followed by deposition of the bottom electrode layer 132, the dielectric layer 134, and the capping liner layer 136. The bottom electrode layer 132 may be formed of titanium nitride (TiN), tantalum nitride (TaN), titanium carbon (TIC), titanium aluminum (TiAl), titanium aluminum carbon (TiAlC), ruthenium (Ru), aluminum (Al), tungsten (W), etc., and may have a thickness in the range of 3-50 nm. The dielectric layer 134 may be formed of a high-k dielectric material such as hafnium oxide (HfO₂), hafnium tantalum oxide (HfTaOₓ), hafnium aluminum oxide (HfAlOₓ), aluminum oxide (AlOₓ), hafnium zirconium oxide (HfZrOₓ), etc., and may have a thickness in the range of 5-50 nm. The capping liner layer 136 may be formed of TiN, TaN, TiC, TiAl, TiAlC, Ru, Al, W, etc., and may have a thickness in the range of 3-50 nm.

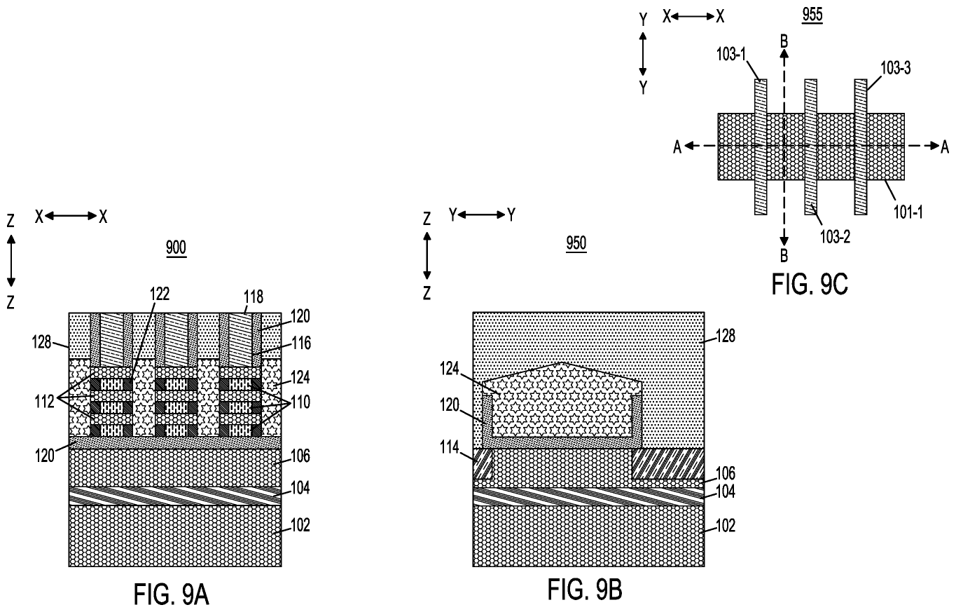

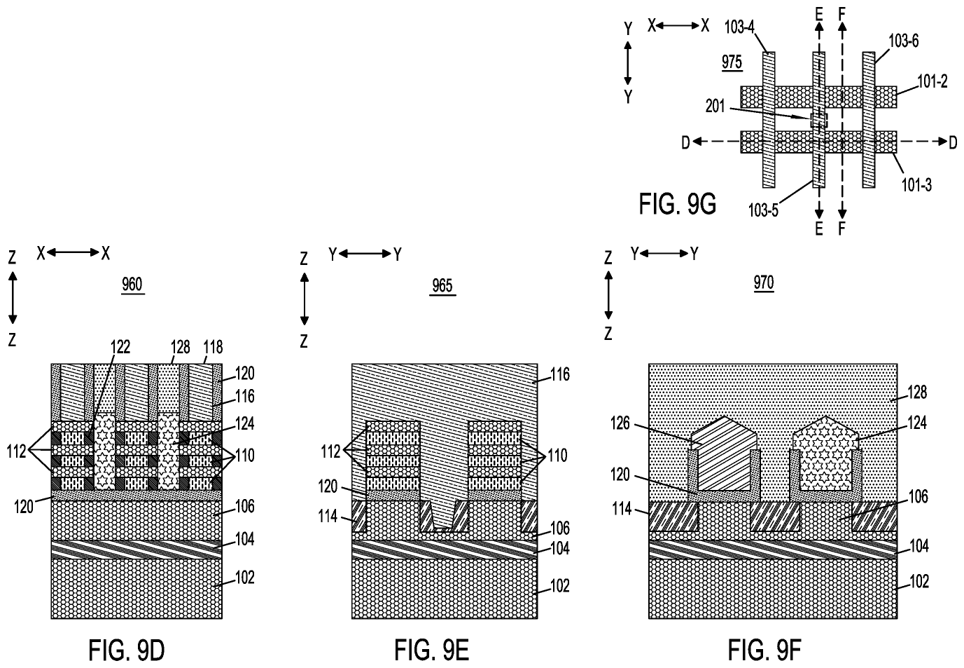

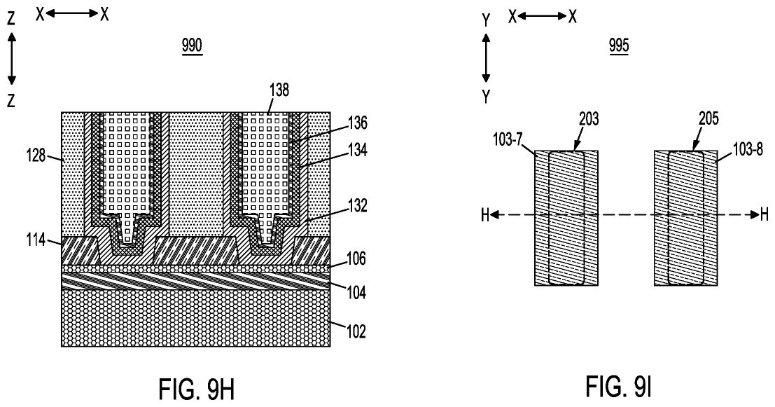

FIGS. 9A-9I show different views of the semiconductor structure of FIGS. 8A-8I following chamfering of the bottom electrode layer 132. FIGS. 9A and 9B show respective cross-sectional views 900 and 950 of the high current capacity transistor region of the semiconductor structure, with FIG. 9C showing a top-down view 955 illustrating where the cross-sectional views 900 and 950 are taken in the high current capacity transistor region of the semiconductor structure. The cross-sectional view 900 of FIG. 9A is taken along the line A-A in the top-down view 955 of FIG. 9C (e.g., along the fin active region 101-1), and the cross-sectional view 950 of FIG. 9B is taken along the line B-B in the top-down view 955 of FIG. 9C (e.g., across the gate regions 103-1, 103-2 and 103-3). FIGS. 9D, 9E and 9F show respective cross-sectional views 960, 965 and 970 of the control circuit region of the semiconductor structure, with FIG. 9G showing a top-down view 975 illustrating where the cross-sectional views 960, 965 and 970 are taken in the control circuit region of the semiconductor structure. The cross-sectional view 960 of FIG. 9D is taken along the line D-D in the top-down view 975 of FIG. 9G (e.g., along the fin active region 101-3), the cross-sectional view 965 of FIG. 9E is taken along the line E-E in the top-down view 975 of FIG. 9G (e.g., along the gate region 103-5), and the cross-sectional view 970 of FIG. 9F is taken along the line F-F in the top-down view 975 of FIG. 9G (e.g., between the gate regions 103-5 and 103-6 across the fin active regions 101-2 and 101-3). FIG. 9H shows a cross-sectional view 990 of the ESD-transient detection circuit region of the semiconductor structure, with FIG. 9I showing a top-down view 995 illustrating where the cross-sectional view 990 is taken in the ESD-transient detection circuit region of the semiconductor structure. The cross-sectional view 990 of FIG. 9H is taken along the line H-H in the top-down view 995 of FIG. 9I (e.g., across the dummy gate regions 103-7 and 103-8).

A spin-on layer 138 is formed over the structure, including fill of the MIM region shown in the cross-sectional view 990 of FIG. 9H. The spin-on layer 138 may be formed of an optical planarization layer (SOH/OPL). The spin-on layer 138 is recessed by RIE, and the capping liner layer 136, the dielectric layer 134 and the bottom electrode layer 132 are then etched by RIE or wet etch processing to result in the structure shown in FIGS. 9A-9I.

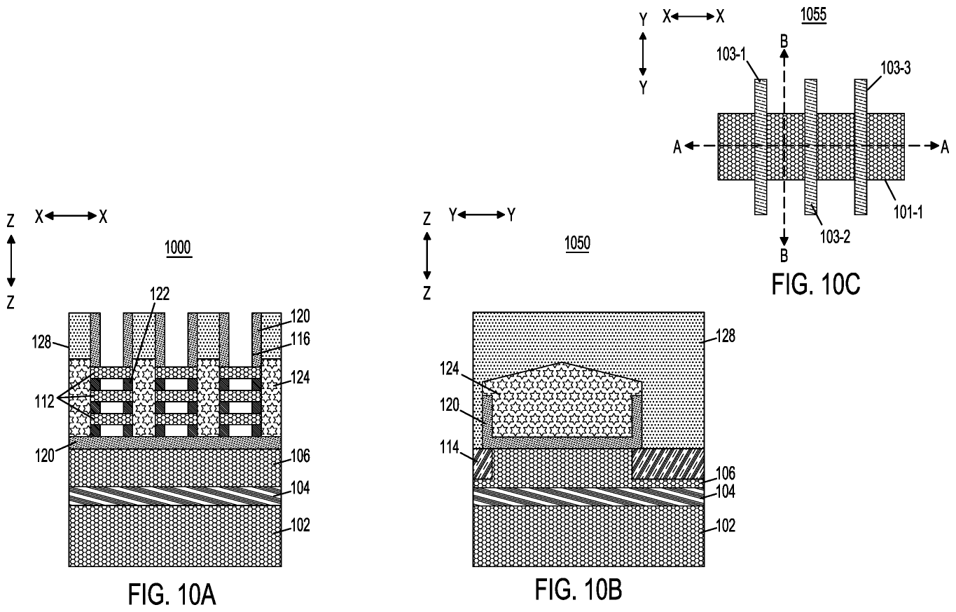

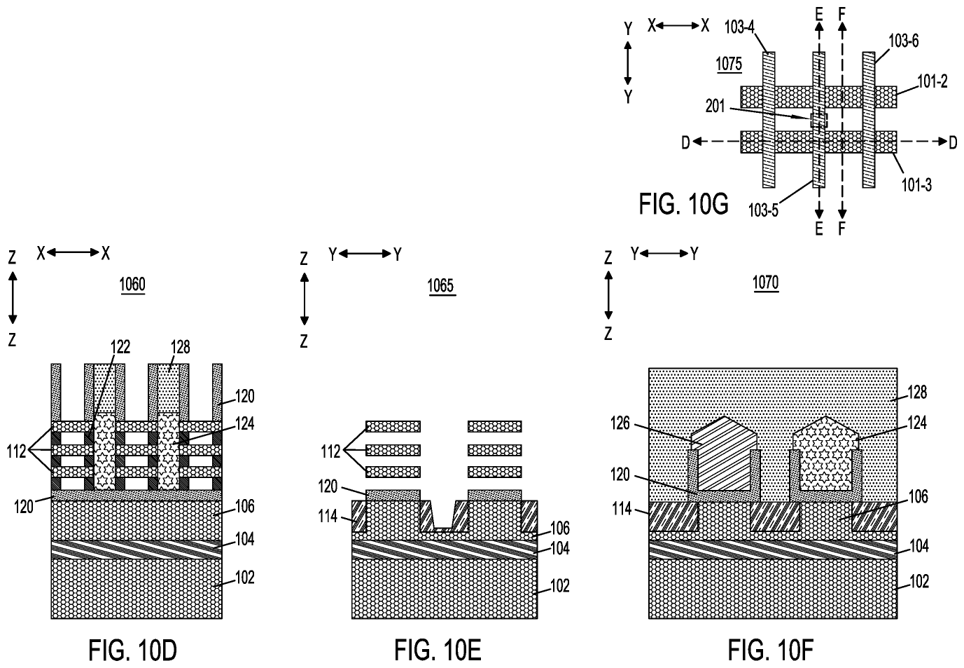

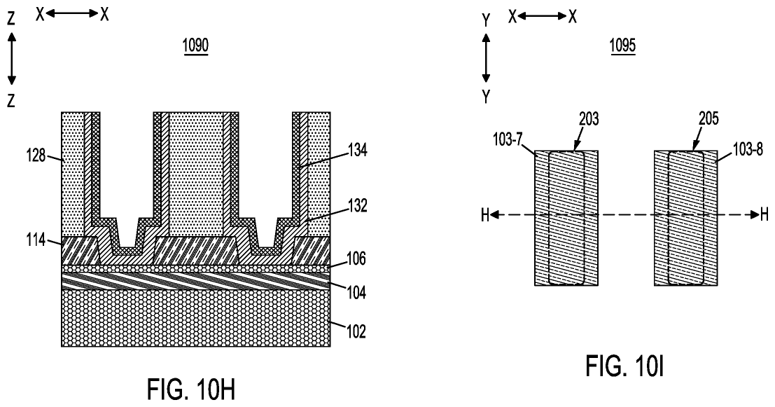

FIGS. 10A-10I show different views of the semiconductor structure of FIGS. 9A-9I following removal of the spin-on layer 138, the capping liner layer 136, remaining portions of the dummy gate layers 116 and gate HM layers 118, and the sacrificial layers 110. FIGS. 10A and 10B show respective cross-sectional views 1000 and 1050 of the high current capacity transistor region of the semiconductor structure, with FIG. 10C showing a top-down view 1055 illustrating where the cross-sectional views 1000 and 1050 are taken in the high current capacity transistor region of the semiconductor structure. The cross-sectional view 1000 of FIG. 10A is taken along the line A-A in the top-down view 1055 of FIG. 10C (e.g., along the fin active region 101-1), and the cross-sectional view 1050 of FIG. 10B is taken along the line B-B in the top-down view 1055 of FIG. 10C (e.g., across the gate regions 103-1, 103-2 and 103-3). FIGS. 10D, 10E and 10F show respective cross-sectional views 1060, 1065 and 1070 of the control circuit region of the semiconductor structure, with FIG. 10G showing a top-down view 1075 illustrating where the cross-sectional views 1060, 1065 and 1070 are taken in the control circuit region of the semiconductor structure. The cross-sectional view 1060 of FIG. 10D is taken along the line D-D in the top-down view 1075 of FIG. 10G (e.g., along the fin active region 101-3), the cross-sectional view 1065 of FIG. 10E is taken along the line E-E in the top-down view 1075 of FIG. 10G (e.g., along the gate region 103-5), and the cross-sectional view 1070 of FIG. 10F is taken along the line F-F in the top-down view 1075 of FIG. 10G (e.g., between the gate regions 103-5 and 103-6 across the fin active regions 101-2 and 101-3). FIG. 10H shows a cross-sectional view 1090 of the ESD-transient detection circuit region of the semiconductor structure, with FIG. 10I showing a top-down view 1095 illustrating where the cross-sectional view 1090 is taken in the ESD-transient detection circuit region of the semiconductor structure. The cross-sectional view 1090 of FIG. 10H is taken along the line H-H in the top-down view 1095 of FIG. 10I (e.g., across the dummy gate regions 103-7 and 103-8).

The spin-on layer 138, the capping liner layer 136, remaining portions of the dummy gate layers 116 and gate HM layers 118, and the sacrificial layers 110 are removed using one or more wet etch and/or selective dry etch (SDE) processes. A high-k pre-clean process is then performed.

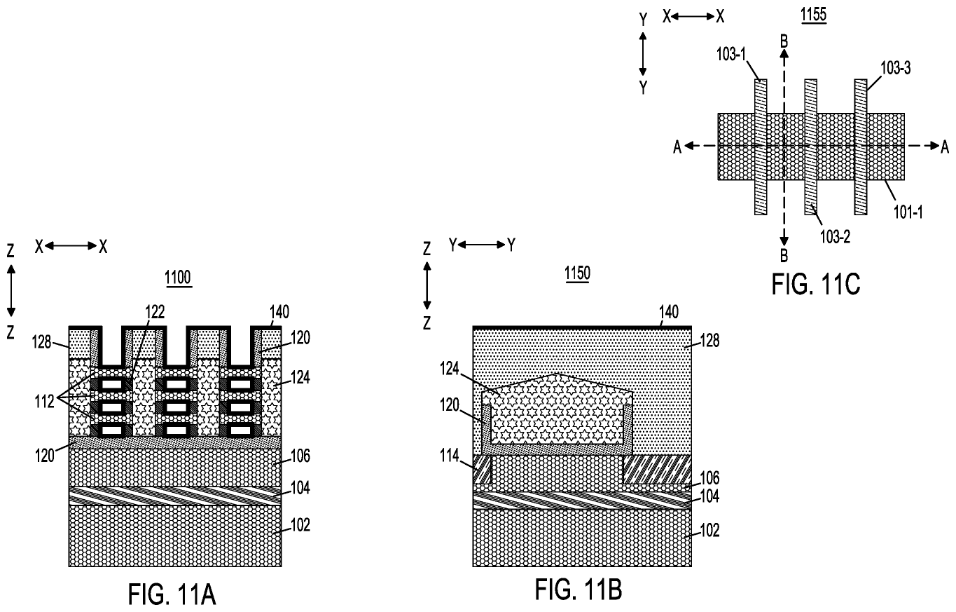

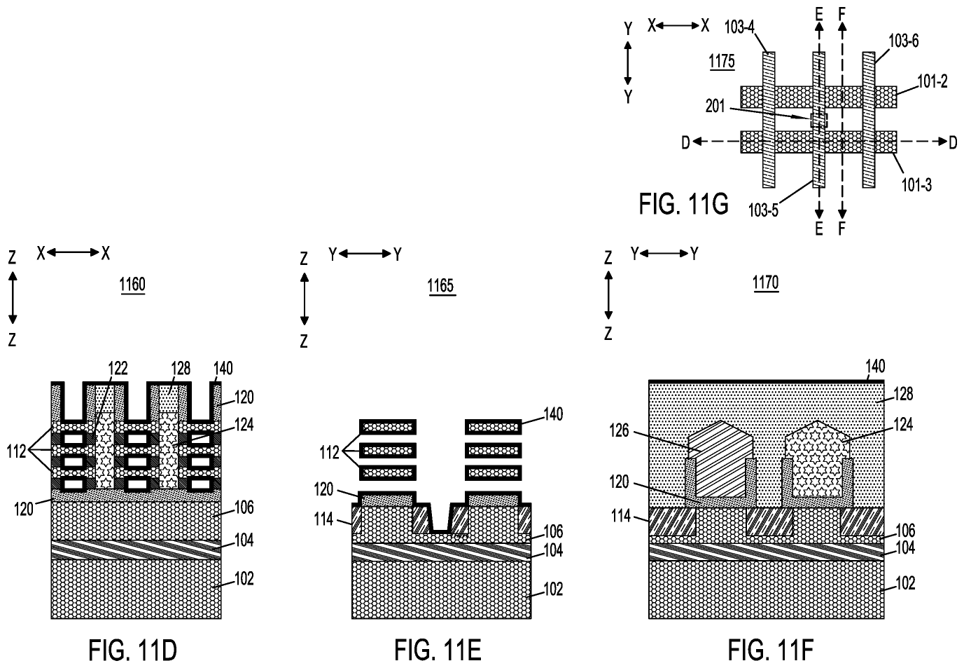

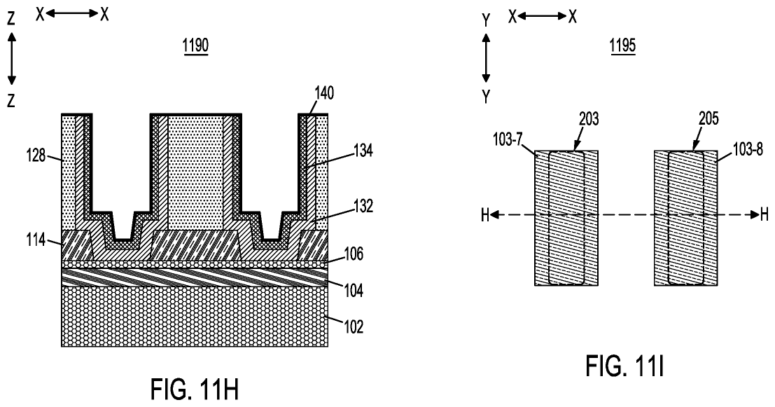

FIGS. 11A-11I show different views of the semiconductor structure of FIGS. 10A-10I following formation of a gate dielectric layer 140. FIGS. 11A and 11B show respective cross-sectional views 1100 and 1150 of the high current capacity transistor region of the semiconductor structure, with FIG. 11C showing a top-down view 1155 illustrating where the cross-sectional views 1100 and 1150 are taken in the high current capacity transistor region of the semiconductor structure. The cross-sectional view 1100 of FIG. 11A is taken along the line A-A in the top-down view 1155 of FIG. 11C (e.g., along the fin active region 101-1), and the cross-sectional view 1150 of FIG. 11B is taken along the line B-B in the top-down view 1155 of FIG. 11C (e.g., across the gate regions 103-1, 103-2 and 103-3). FIGS. 11D, 11E and 11F show respective cross-sectional views 1160, 1165 and 1170 of the control circuit region of the semiconductor structure, with FIG. 11G showing a top-down view 1175 illustrating where the cross-sectional views 1160, 1165 and 1170 are taken in the control circuit region of the semiconductor structure. The cross-sectional view 1160 of FIG. 11D is taken along the line D-D in the top-down view 1175 of FIG. 11G (e.g., along the fin active region 101-3), the cross-sectional view 1165 of FIG. 11E is taken along the line E-E in the top-down view 1175 of FIG. 11G (e.g., along the gate region 103-5), and the cross-sectional view 1170 of FIG. 11F is taken along the line F-F in the top-down view 1175 of FIG. 11G (e.g., between the gate regions 103-5 and 103-6 across the fin active regions 101-2 and 101-3). FIG. 11H shows a cross-sectional view 1190 of the ESD-transient detection circuit region of the semiconductor structure, with FIG. 11I showing a top-down view 1195 illustrating where the cross-sectional view 1190 is taken in the ESD-transient detection circuit region of the semiconductor structure. The cross-sectional view 1190 of FIG. 11H is taken along the line H-H in the top-down view 1195 of FIG. 11I (e.g., across the dummy gate regions 103-7 and 103-8).

The gate dielectric layer 140 may be conformally deposited in the structure, and may be formed of a high-k material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer 140 may have a uniform thickness in the range of 1 nm to 3 nm. A reliability anneal is then performed. Advantageously, the reliability anneal in the ESD-transient detection circuit region shown in FIG. 11H provides very good leakage and reliability performance for the capacitor which will be formed.

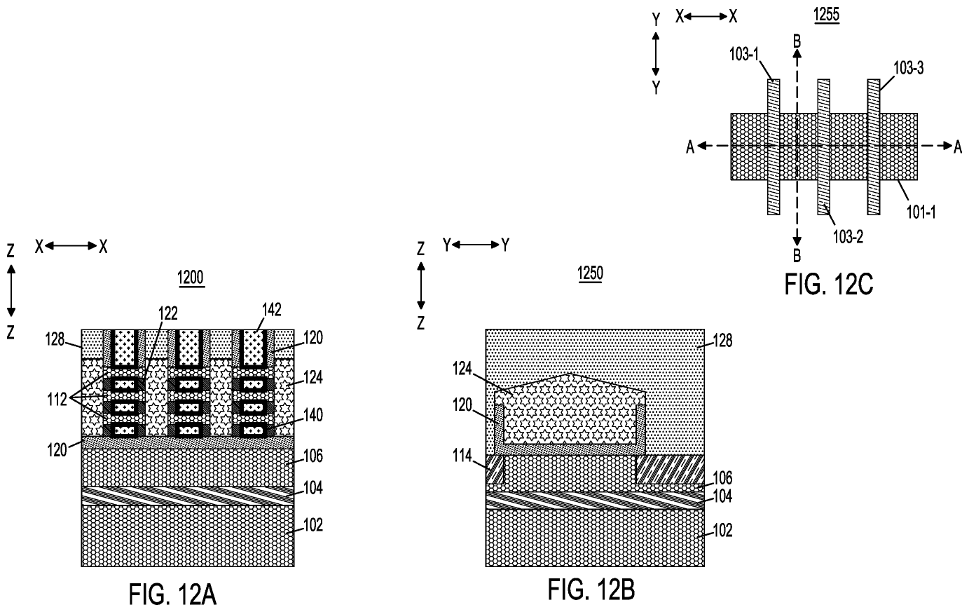

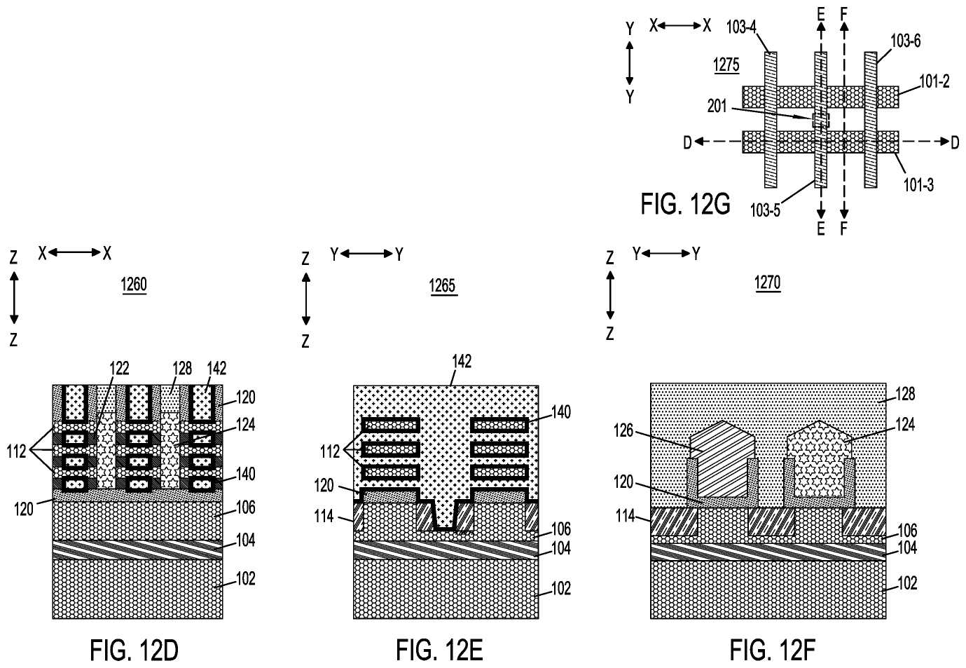

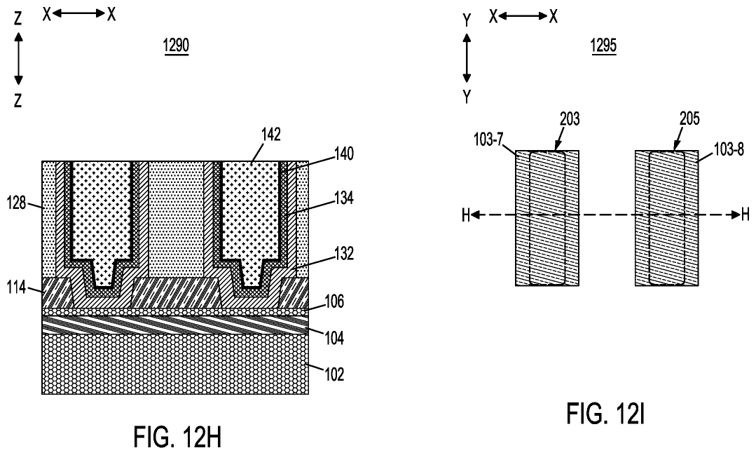

FIGS. 12A-12I show different views of the semiconductor structure of FIGS. 11A-11I following formation of a gate conductor layer 142. FIGS. 12A and 12B show respective cross-sectional views 1200 and 1250 of the high current capacity transistor region of the semiconductor structure, with FIG. 12C showing a top-down view 1255 illustrating where the cross-sectional views 1200 and 1250 are taken in the high current capacity transistor region of the semiconductor structure. The cross-sectional view 1200 of FIG. 12A is taken along the line A-A in the top-down view 1255 of FIG. 12C (e.g., along the fin active region 101-1), and the cross-sectional view 1250 of FIG. 12B is taken along the line B-B in the top-down view 1255 of FIG. 12C (e.g., across the gate regions 103-1, 103-2 and 103-3). FIGS. 12D, 12E and 12F show respective cross-sectional views 1260, 1265 and 1270 of the control circuit region of the semiconductor structure, with FIG. 12G showing a top-down view 1275 illustrating where the cross-sectional views 1260, 1265 and 1270 are taken in the control circuit region of the semiconductor structure. The cross-sectional view 1260 of FIG. 12D is taken along the line D-D in the top-down view 1275 of FIG. 12G (e.g., along the fin active region 101-3), the cross-sectional view 1265 of FIG. 12E is taken along the line E-E in the top-down view 1275 of FIG. 12G (e.g., along the gate region 103-5), and the cross-sectional view 1270 of FIG. 12F is taken along the line F-F in the top-down view 1275 of FIG. 12G (e.g., between the gate regions 103-5 and 103-6 across the fin active regions 101-2 and 101-3). FIG. 12H shows a cross-sectional view 1290 of the ESD-transient detection circuit region of the semiconductor structure, with FIG. 12I showing a top-down view 1295 illustrating where the cross-sectional view 1290 is taken in the ESD-transient detection circuit region of the semiconductor structure. The cross-sectional view 1290 of FIG. 12H is taken along the line H-H in the top-down view 1295 of FIG. 12I (e.g., across the dummy gate regions 103-7 and 103-8).

The gate conductor layer 142 may include a work function metal (WFM) and a conductive metal (e.g., tungsten (W)). The WFM for the gate conductor layer 142 may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer 142 as desired. In the ESD-transient detection circuit region, the material of the gate conductor layer 142 provides a top electrode for the capacitor.

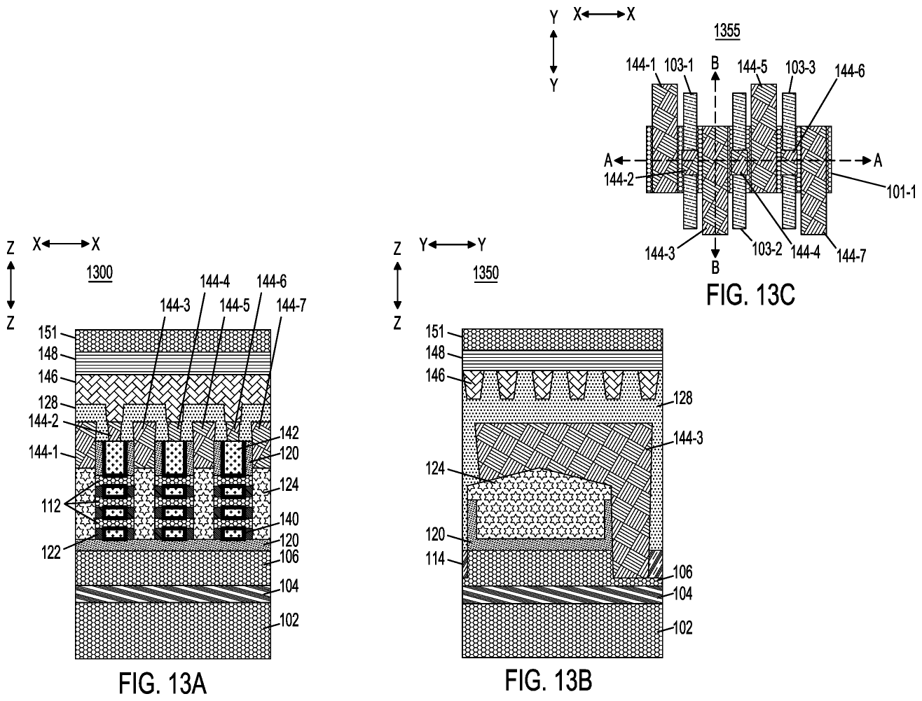

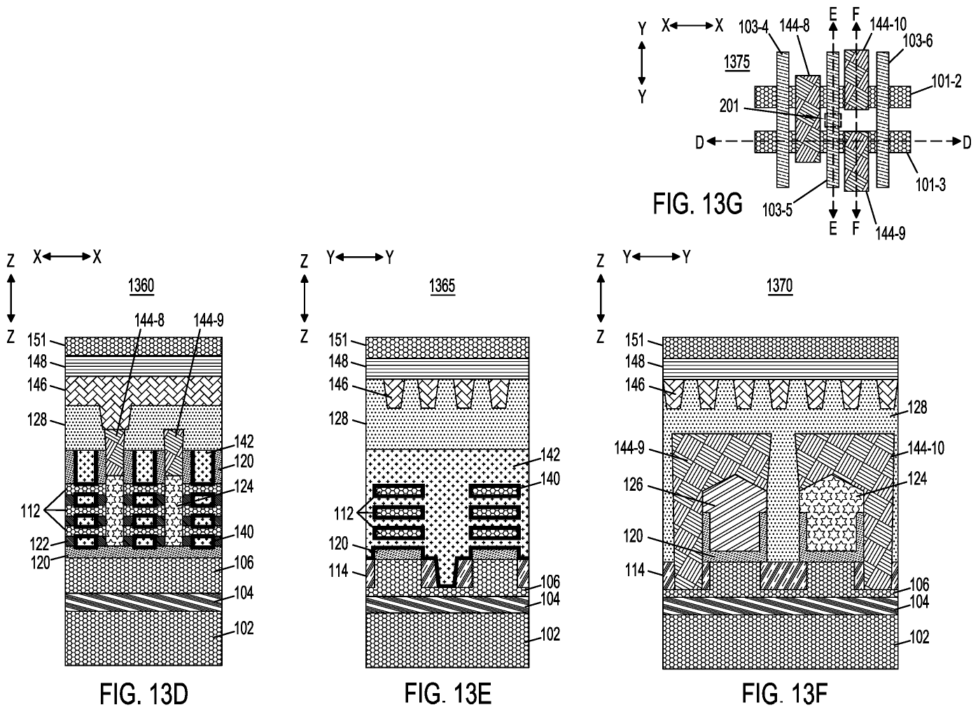

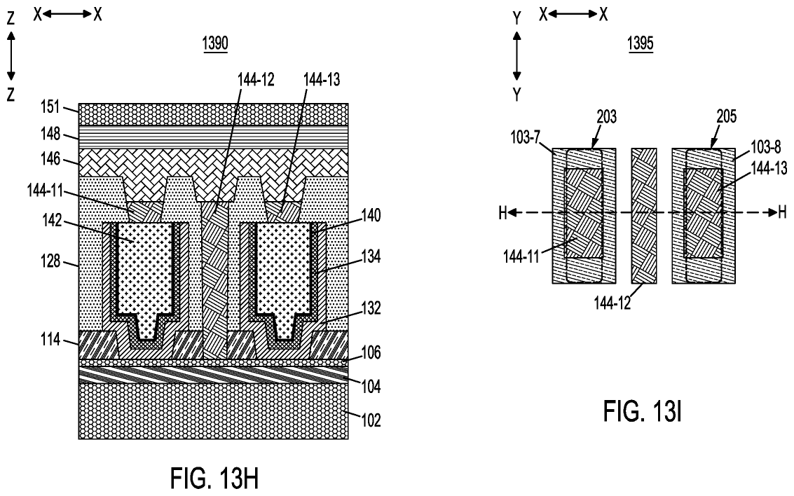

FIGS. 13A-13I show different views of the semiconductor structure of FIGS. 12A-12I following formation of middle-of-line (MOL) contacts 144-1 through 144-13, a frontside BEOL metallization layer 146, a frontside BEOL region 148, and bonding to a carrier wafer 151. FIGS. 13A and 13B show respective cross-sectional views 1300 and 1350 of the high current capacity transistor region of the semiconductor structure, with FIG. 13C showing a top-down view 1355 illustrating where the cross-sectional views 1300 and 1350 are taken in the high current capacity transistor region of the semiconductor structure. The cross-sectional view 1300 of FIG. 13A is taken along the line A-A in the top-down view 1355 of FIG. 13C (e.g., along the fin active region 101-1), and the cross-sectional view 1350 of FIG. 13B is taken along the line B-B in the top-down view 1355 of FIG. 13C (e.g., across the gate regions 103-1, 103-2 and 103-3). FIGS. 13D, 13E and 13F show respective cross-sectional views 1360, 1365 and 1370 of the control circuit region of the semiconductor structure, with FIG. 13G showing a top-down view 1375 illustrating where the cross-sectional views 1360, 1365 and 1370 are taken in the control circuit region of the semiconductor structure. The cross-sectional view 1360 of FIG. 13D is taken along the line D-D in the top-down view 1375 of FIG. 13G (e.g., along the fin active region 101-3), the cross-sectional view 1365 of FIG. 13E is taken along the line E-E in the top-down view 1375 of FIG. 13G (e.g., along the gate region 103-5), and the cross-sectional view 1370 of FIG. 13F is taken along the line F-F in the top-down view 1375 of FIG. 13G (e.g., between the gate regions 103-5 and 103-6 across the fin active regions 101-2 and 101-3). FIG. 13H shows a cross-sectional view 1390 of the ESD-transient detection circuit region of the semiconductor structure, with FIG. 13I showing a top-down view 1395 illustrating where the cross-sectional view 1390 is taken in the ESD-transient detection circuit region of the semiconductor structure. The cross-sectional view 1390 of FIG. 13H is taken along the line H-H in the top-down view 1395 of FIG. 13I (e.g., across the dummy gate regions 103-7 and 103-8).

The MOL contacts include: source/drain MOL contacts 144-1, 144-3, 144-5 and 144-7 and gate MOL contacts 144-2, 144-4 and 144-6 for the ESD clamp device as shown in FIGS. 13A-13C; source/drain MOL contacts 144-8, 144-9 and 144-10 for the control circuit as shown in FIGS. 13D-13G; and top electrode MOL contacts 144-11 and 144-13 and bottom electrode MOL contact 144-12 for the capacitor as shown in FIGS. 13H and 13I. As shown, some of the MOL contacts including MOL contacts 144-1, 144-3, 144-5, 144-7, 144-9, 144-10 and 144-12 include VBPR portions for connection to the backside of the structure, while other of the MOL contacts including MOL contacts 144-2, 144-4, 144-5, 144-6, 144-11 and 144-13 connect to the frontside BEOL metallization layer 146 (M1). The MOL contacts 144-1 through 144-13 along with the frontside BEOL metallization layer 146 (M1) are formed by patterning of openings in the frontside ILD layer 128. The frontside BEOL region 148 is then formed, followed by bonding to the carrier wafer 151.

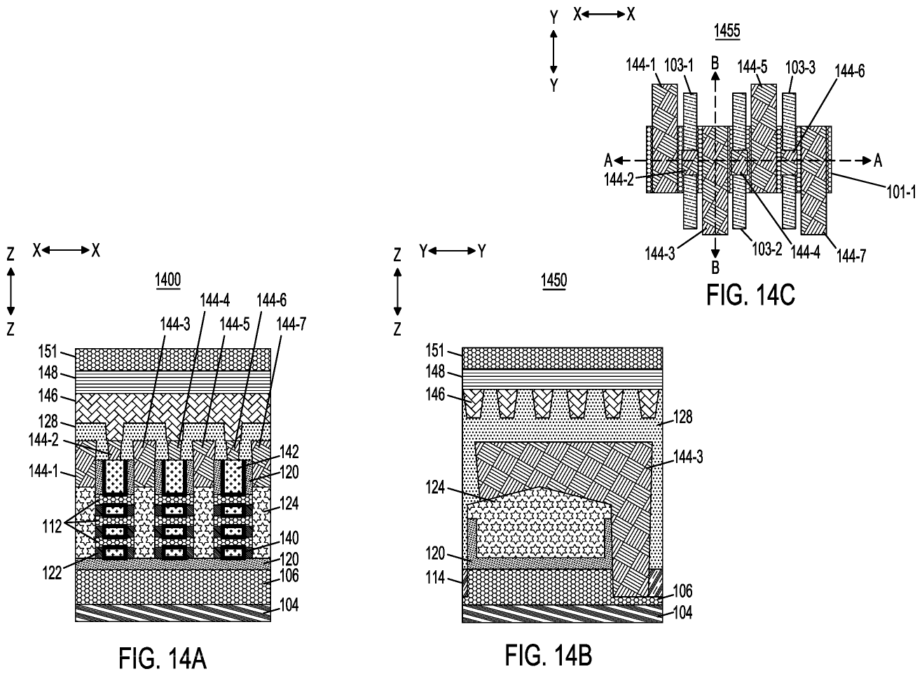

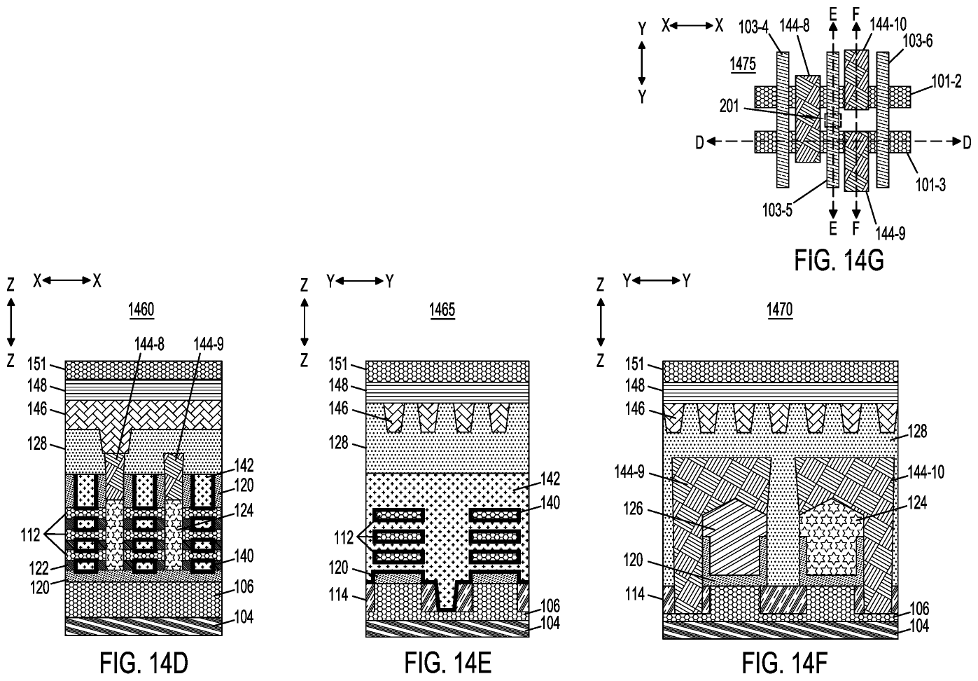

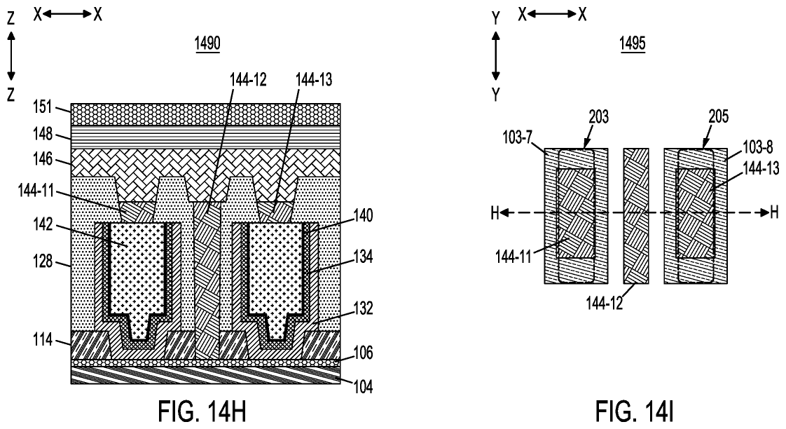

FIGS. 14A-14I show different views of the semiconductor structure of FIGS. 13A-13I following a wafer flip and removal of the substrate 102. Following the wafer flip, the substrate 102 may be removed via a substrate grinding, CMP and/or wet etch process which stops on the etch stop layer 104. FIGS. 14A and 14B show respective cross-sectional views 1400 and 1450 of the high current capacity transistor region of the semiconductor structure, with FIG. 14C showing a top-down view 1455 illustrating where the cross-sectional views 1400 and 1450 are taken in the high current capacity transistor region of the semiconductor structure. The cross-sectional view 1400 of FIG. 14A is taken along the line A-A in the top-down view 1455 of FIG. 14C (e.g., along the fin active region 101-1), and the cross-sectional view 1450 of FIG. 14B is taken along the line B-B in the top-down view 1455 of FIG. 14C (e.g., across the gate regions 103-1, 103-2 and 103-3). FIGS. 14D, 14E and 14F show respective cross-sectional views 1460, 1465 and 1470 of the control circuit region of the semiconductor structure, with FIG. 14G showing a top-down view 1475 illustrating where the cross-sectional views 1460, 1465 and 1470 are taken in the control circuit region of the semiconductor structure. The cross-sectional view 1460 of FIG. 14D is taken along the line D-D in the top-down view 1475 of FIG. 14G (e.g., along the fin active region 101-3), the cross-sectional view 1465 of FIG. 14E is taken along the line E-E in the top-down view 1475 of FIG. 14G (e.g., along the gate region 103-5), and the cross-sectional view 1470 of FIG. 14F is taken along the line F-F in the top-down view 1475 of FIG. 14G (e.g., between the gate regions 103-5 and 103-6 across the fin active regions 101-2 and 101-3). FIG. 14H shows a cross-sectional view 1490 of the ESD-transient detection circuit region of the semiconductor structure, with FIG. 14I showing a top-down view 1495 illustrating where the cross-sectional view 1490 is taken in the ESD-transient detection circuit region of the semiconductor structure. The cross-sectional view 1490 of FIG. 14H is taken along the line H-H in the top-down view 1495 of FIG. 14I (e.g., across the dummy gate regions 103-7 and 103-8).

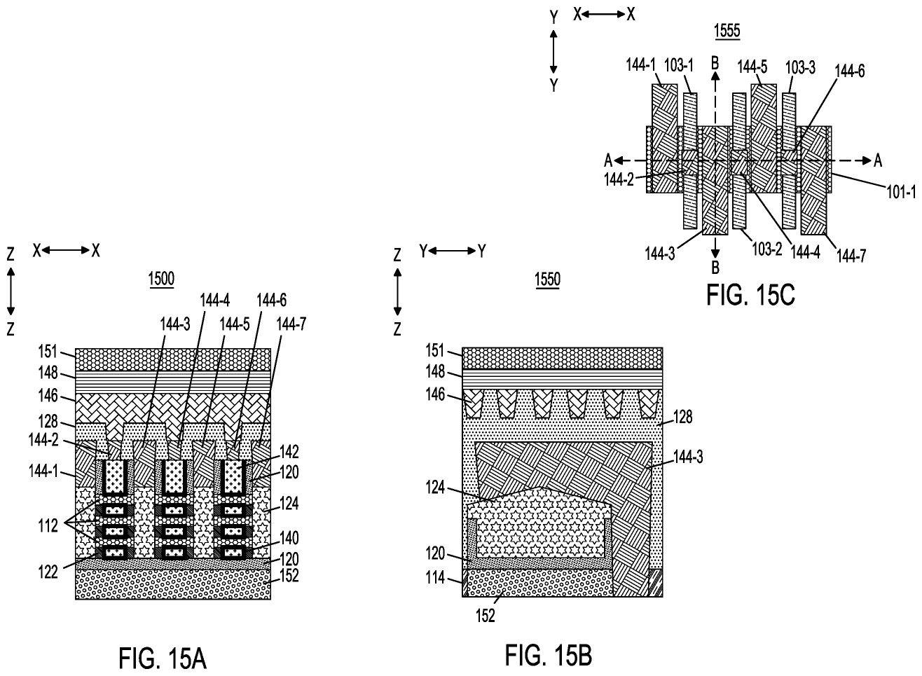

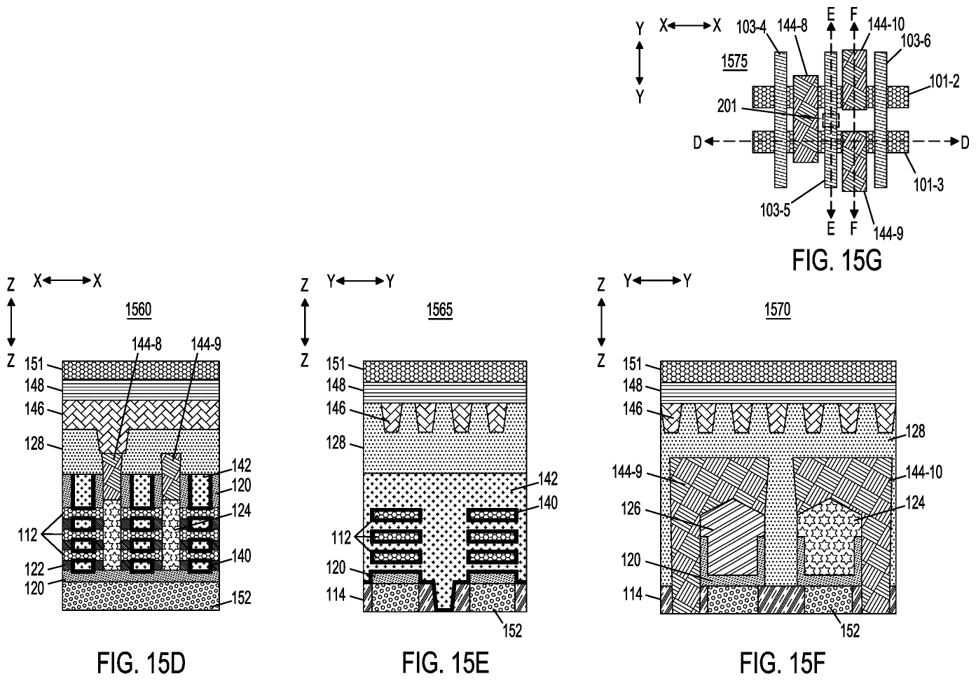

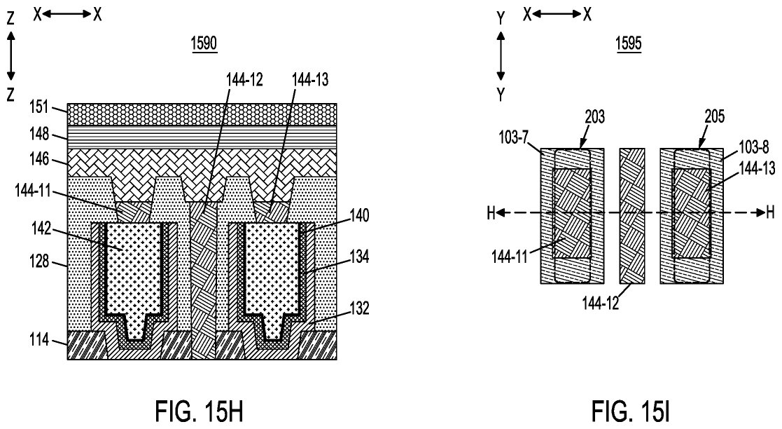

FIGS. 15A-15I show different views of the semiconductor structure of FIGS. 14A-14I following removal of the etch stop layer 104 and the semiconductor layer 106, and following formation of backside ILD layer 152. FIGS. 15A and 15B show respective cross-sectional views 1500 and 1550 of the high current capacity transistor region of the semiconductor structure, with FIG. 15C showing a top-down view 1555 illustrating where the cross-sectional views 1500 and 1550 are taken in the high current capacity transistor region of the semiconductor structure. The cross-sectional view 1500 of FIG. 15A is taken along the line A-A in the top-down view 1555 of FIG. 15C (e.g., along the fin active region 101-1), and the cross-sectional view 1550 of FIG. 15B is taken along the line B-B in the top-down view 1555 of FIG. 15C (e.g., across the gate regions 103-1, 103-2 and 103-3). FIGS. 15D, 15E and 15F show respective cross-sectional views 1560, 1565 and 1570 of the control circuit region of the semiconductor structure, with FIG. 15G showing a top-down view 1575 illustrating where the cross-sectional views 1560, 1565 and 1570 are taken in the control circuit region of the semiconductor structure. The cross-sectional view 1560 of FIG. 15D is taken along the line D-D in the top-down view 1575 of FIG. 15G (e.g., along the fin active region 101-3), the cross-sectional view 1565 of FIG. 15E is taken along the line E-E in the top-down view 1575 of FIG. 15G (e.g., along the gate region 103-5), and the cross-sectional view 1570 of FIG. 15F is taken along the line F-F in the top-down view 1575 of FIG. 15G (e.g., between the gate regions 103-5 and 103-6 across the fin active regions 101-2 and 101-3). FIG. 15H shows a cross-sectional view 1590 of the ESD-transient detection circuit region of the semiconductor structure, with FIG. 15I showing a top-down view 1595 illustrating where the cross-sectional view 1590 is taken in the ESD-transient detection circuit region of the semiconductor structure. The cross-sectional view 1590 of FIG. 15H is taken along the line H-H in the top-down view 1595 of FIG. 15I (e.g., across the dummy gate regions 103-7 and 103-8).

The etch stop layer 104 and the semiconductor layer 106 may be removed using any suitable etch processing. The removal of the semiconductor layer 106 reveals the VBPRs of the MOL contacts 144-1, 144-3, 144-5, 144-7, 144-9, 144-10 and 144-12 along with the gate backside vias 201, 203 and 205. Material for the backside ILD layer 152 is then deposited and planarized (e.g., using CMP or other suitable processing). The backside ILD layer 152 may be formed of similar materials as the frontside ILD layer 128.

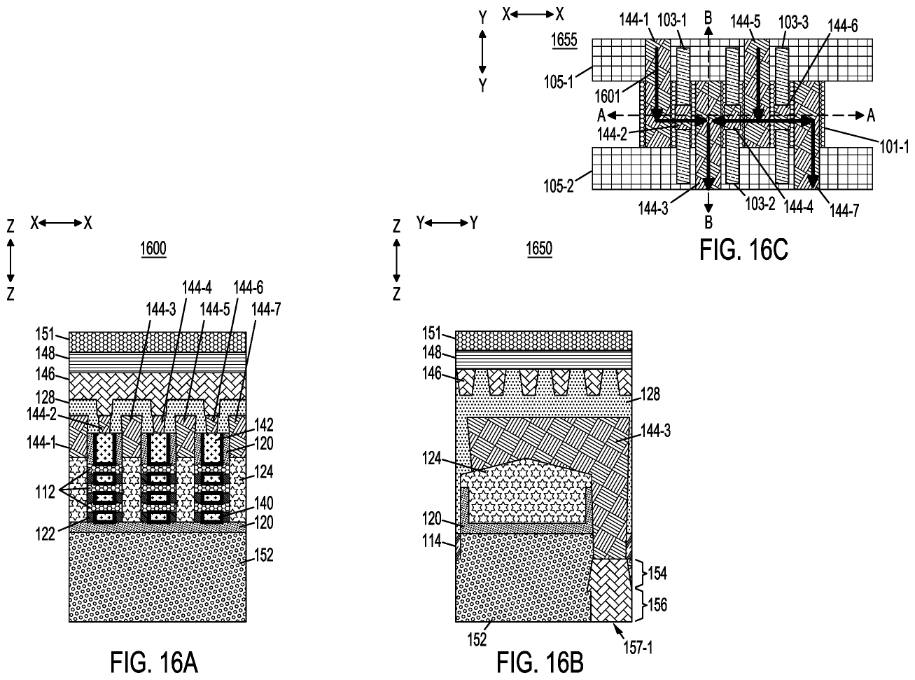

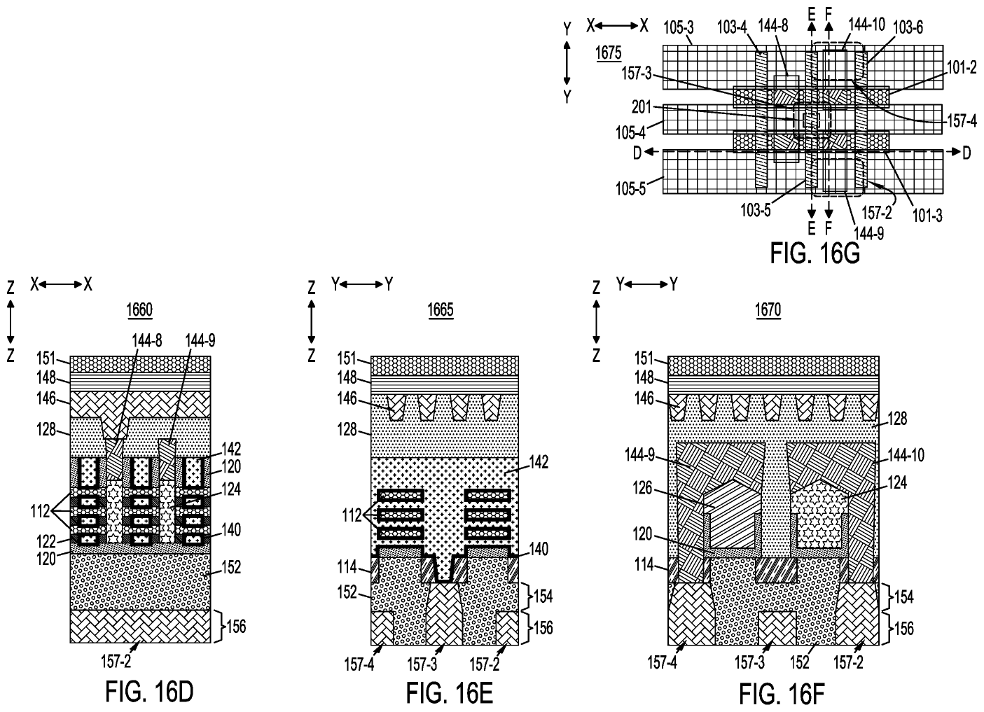

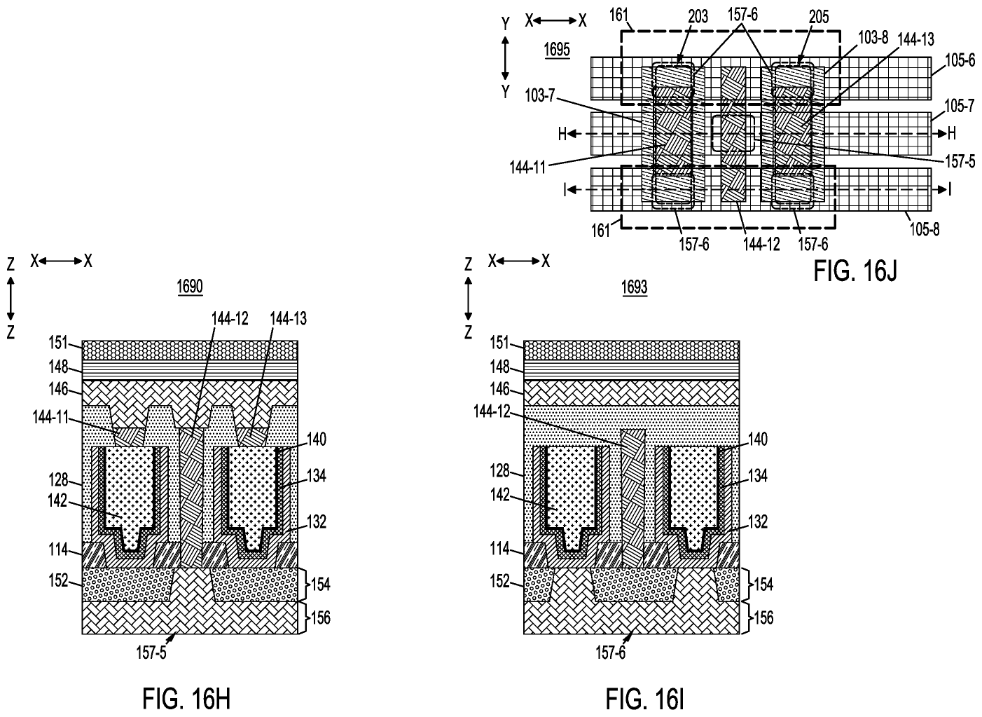

FIGS. 16A-16J show different views of the semiconductor structure of FIGS. 15A-15I following formation of backside interconnects including a backside via layer 154 and a backside metallization layer 156. FIGS. 16A and 16B show respective cross-sectional views 1600 and 1650 of the high current capacity transistor region of the semiconductor structure, with FIG. 16C showing a top-down view 1655 illustrating where the cross-sectional views 1600 and 1650 are taken in the high current capacity transistor region of the semiconductor structure. FIG. 16C also shows connections 105-1 and 105-2 to power rails (e.g., to Vdd and Vss, respectively). The cross-sectional view 1600 of FIG. 16A is taken along the line A-A in the top-down view 1655 of FIG. 16C (e.g., along the fin active region 101-1), and the cross-sectional view 1650 of FIG. 16B is taken along the line B-B in the top-down view 1655 of FIG. 16C (e.g., across the gate regions 103-1, 103-2 and 103-3). FIGS. 16D, 16E and 16F show respective cross-sectional views 1660, 1665 and 1670 of the control circuit region of the semiconductor structure, with FIG. 16G showing a top-down view 1675 illustrating where the cross-sectional views 1660, 1665 and 1670 are taken in the control circuit region of the semiconductor structure. FIG. 16G also shows connections 105-3, 105-4 and 105-5. The connections 105-3 and 105-5 are to power rails (e.g., Vdd and Vss, respectively), while the connection 105-4 is to an inverter input. The cross-sectional view 1660 of FIG. 16D is taken along the line D-D in the top-down view 1675 of FIG. 16G (e.g., along the fin active region 101-3), the cross-sectional view 1665 of FIG. 16E is taken along the line E-E in the top-down view 1675 of FIG. 16G (e.g., along the gate region 103-5), and the cross-sectional view 1670 of FIG. 16F is taken along the line F-F in the top-down view 1675 of FIG. 16G (e.g., between the gate regions 103-5 and 103-6 across the fin active regions 101-2 and 101-3). FIGS. 16H and 16I show respective cross-sectional views 1690 and 1693 of the ESD-transient detection circuit region of the semiconductor structure, with FIG. 16J showing a top-down view 1695 illustrating where the cross-sectional views 1690 and 1693 are taken in the ESD-transient detection circuit region of the semiconductor structure. FIG. 16J also shows connections 105-6, 105-7 and 105-8. The connections 105-6 and 105-8 are for a to-be-formed resistor, while the connection 105-7 is to a power rail (e.g., Vss). The cross-sectional view 1690 of FIG. 16H is taken along the line H-H in the top-down view 1695 of FIG. 16J (e.g., across the dummy gate regions 103-7 and 103-8 where a connection 105-7 to the power rail is formed), and the cross-sectional view 1693 of FIG. 16I is taken along the line I-I in the top-down view 1695 of FIG. 16J (e.g., across the dummy gate regions 103-7 and 103-8 where connections 105-6 and 105-8 to the resistor are formed).

The backside via layer 154 (V1) and backside metallization layer 156 (M1) are formed by patterning openings in the backside ILD layer 152 and then depositing metallization material. Shown in FIG. 16B is an ESD clamp device contact 157-1 for the Vss power rail, and shown in FIG. 16C is a current path 1601 for an ESD event where the high current capacity transistor is connected in parallel to send excessive current to the Vss (e.g., ground) power rail. Shown in FIGS. 16D-16G is a control device (e.g., inverter) contact 157-2 for the Vss power rail, a contact 157-3 for the control device input (IN), and a contact 157-4 for the Vdd power rail. Shown in FIGS. 16H-16J is a contact 157-5 for a frontside connection to a top electrode (e.g., 142) of the capacitor and a contact 157-6 for backside connection between the bottom electrode layer 132 of the capacitor and the resistor (to be formed).

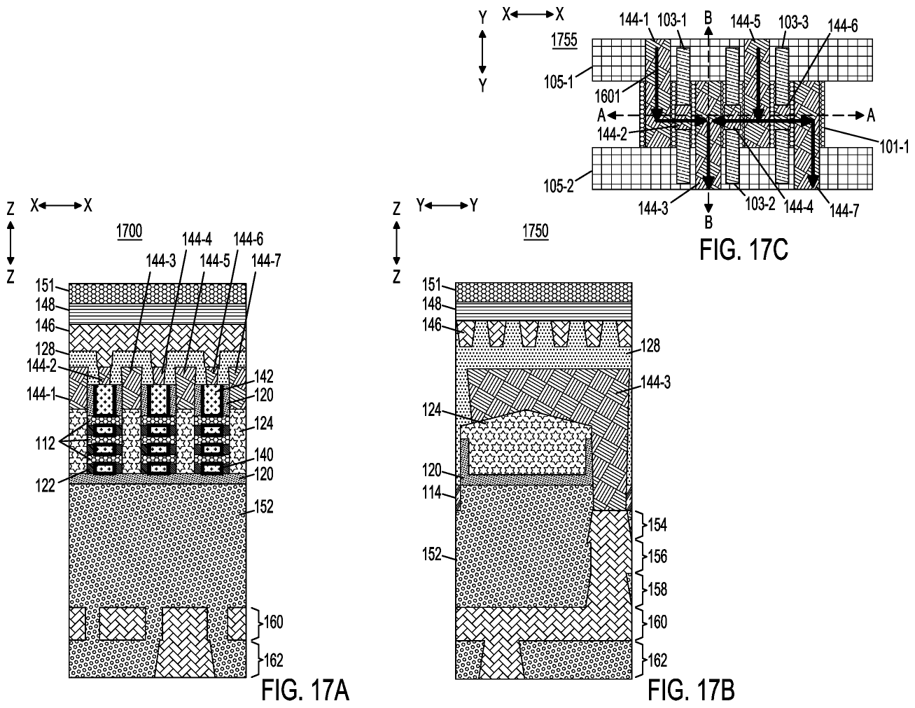

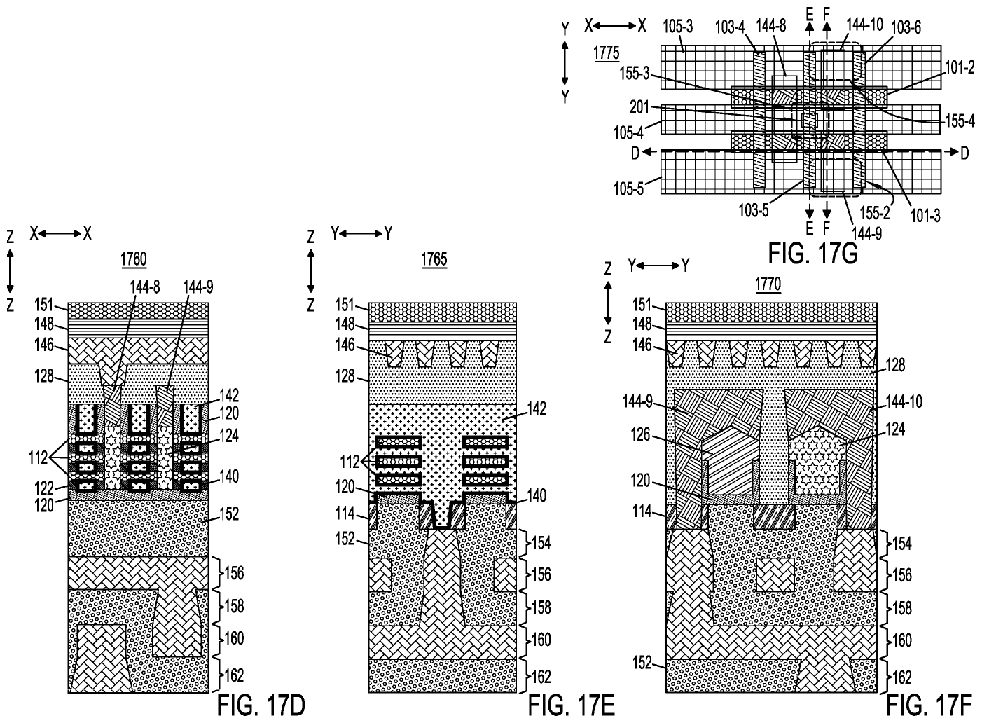

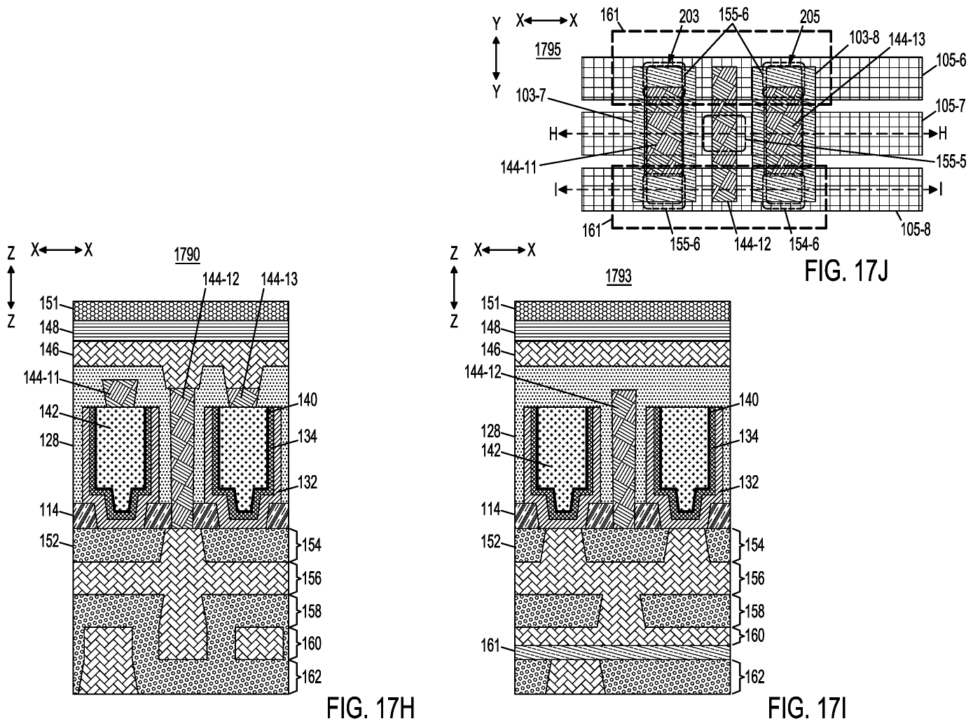

FIGS. 17A-17J show different views of the semiconductor structure of FIGS. 16A-16J following formation of backside via layer 158, backside metallization layer 159, resistor 161 and backside via layer 162. FIGS. 17A and 17B show respective cross-sectional views 1700 and 1750 of the high current capacity transistor region of the semiconductor structure, with FIG. 17C showing a top-down view 1755 illustrating where the cross-sectional views 1700 and 1750 are taken in the high current capacity transistor region of the semiconductor structure. The cross-sectional view 1700 of FIG. 17A is taken along the line A-A in the top-down view 1755 of FIG. 17C (e.g., along the fin active region 101-1), and the cross-sectional view 1750 of FIG. 17B is taken along the line B-B in the top-down view 1755 of FIG. 17C (e.g., across the gate regions 103-1, 103-2 and 103-3). FIGS. 17D, 17E and 17F show respective cross-sectional views 1760, 1765 and 1770 of the control circuit region of the semiconductor structure, with FIG. 17G showing a top-down view 1775 illustrating where the cross-sectional views 1760, 1765 and 1770 are taken in the control circuit region of the semiconductor structure. The cross-sectional view 1760 of FIG. 17D is taken along the line D-D in the top-down view 1775 of FIG. 17G (e.g., along the fin active region 101-3), the cross-sectional view 1765 of FIG. 17E is taken along the line E-E in the top-down view 1775 of FIG. 17G (e.g., along the gate region 103-5), and the cross-sectional view 1770 of FIG. 17F is taken along the line F-F in the top-down view 1775 of FIG. 17G (e.g., between the gate regions 103-5 and 103-6 across the fin active regions 101-2 and 101-3). FIGS. 17H and 17I show respective cross-sectional views 1790 and 1793 of the ESD-transient detection circuit region of the semiconductor structure, with FIG. 17J showing a top-down view 1795 illustrating where the cross-sectional views 1790 and 1793 are taken in the ESD-transient detection circuit region of the semiconductor structure. The cross-sectional view 1790 of FIG. 17H is taken along the line H-H in the top-down view 1795 of FIG. 17J (e.g., across the dummy gate regions 103-7 and 103-8 where the connection 105-7 to the power rail is formed), and the cross-sectional view 1793 of FIG. 17I is taken along the line I-I in the top-down view 1795 of FIG. 17J (e.g., across the dummy gate regions 103-7 and 103-8 where connections 105-6 and 105-8 to the resistor 161 are formed).

The backside via layer 158 (V2), the backside metallization layer 159 (M2) and backside via layer 162 (V3) are formed be depositing additional material for the backside ILD layer 152, and then patterning openings therein and depositing metallization material in the openings. As shown in FIG. 17I, in the ESD-transient detection circuit region of the semiconductor structure, a resistor 161 is formed between the backside metallization layer 159 and the backside via layer 162. The resistor 161 is connected to the bottom electrode layer 132 through the various backside via and metallization layers 154, 156, 158 and 159. The resistor 161 is also connected to the Vss power rail through the backside via layer 162. The resistor 161 may be formed of a tungsten silicide (WSi), titanium nitride (TiN), high resistance polysilicon, etc.

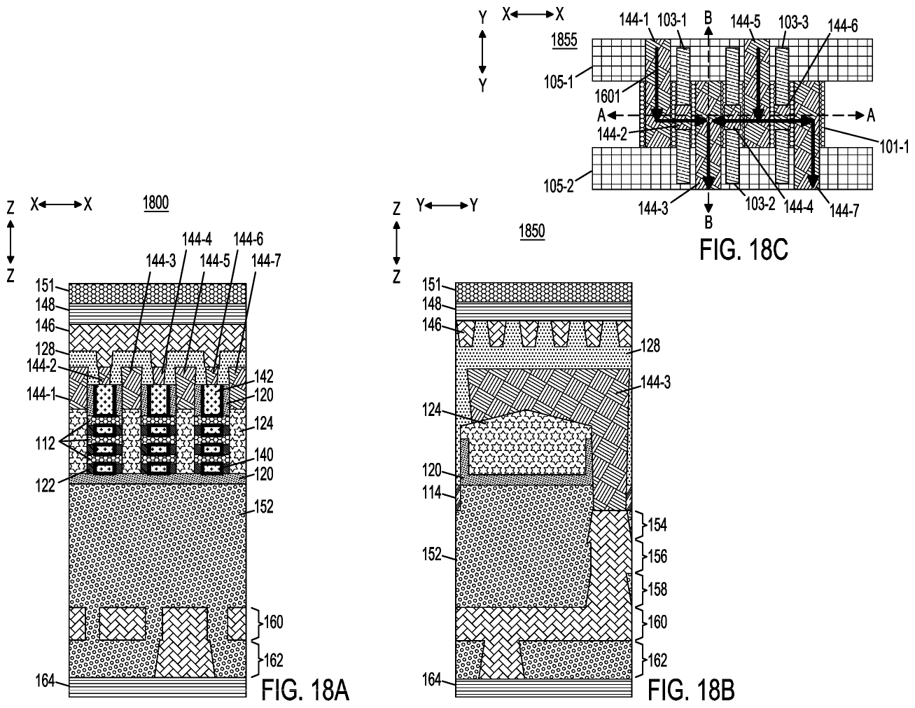

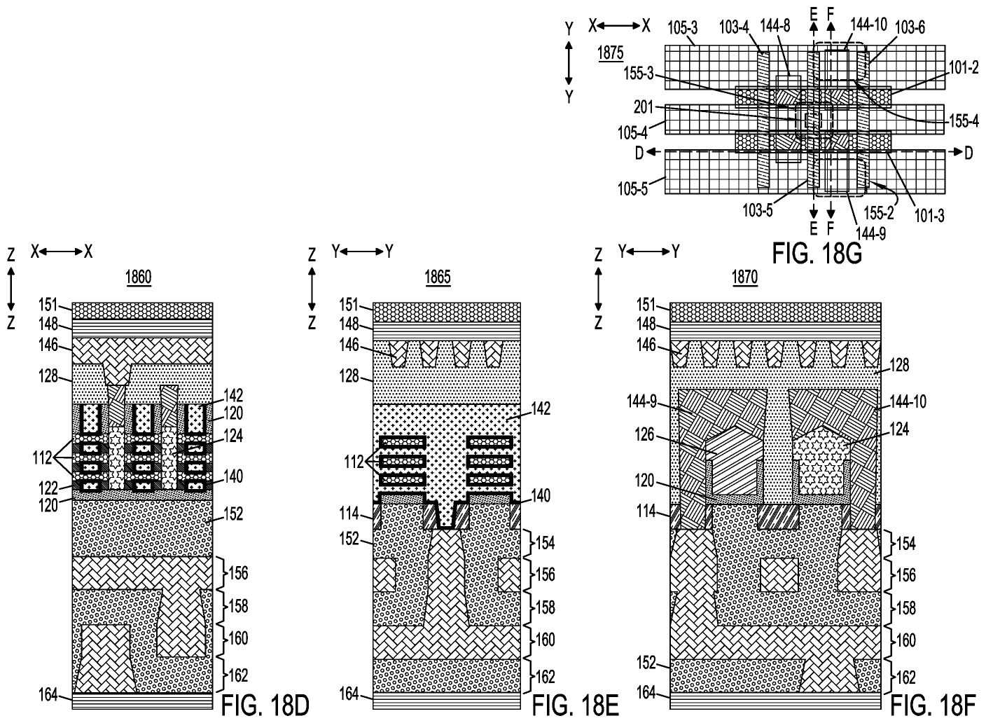

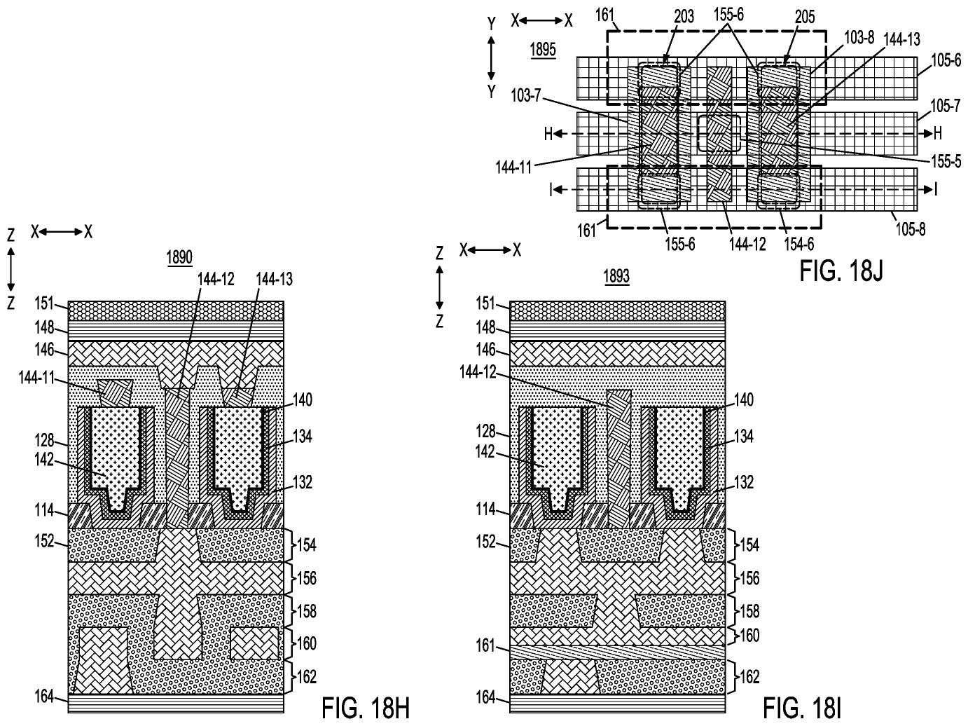

FIGS. 18A-18J show different views of the semiconductor structure of FIGS. 17A-17J following formation of a BSPDN 164. FIGS. 18A and 18B show respective cross-sectional views 1800 and 1850 of the high current capacity transistor region of the semiconductor structure, with FIG. 18C showing a top-down view 1855 illustrating where the cross-sectional views 1800 and 1850 are taken in the high current capacity transistor region of the semiconductor structure. The cross-sectional view 1800 of FIG. 18A is taken along the line A-A in the top-down view 1855 of FIG. 18C (e.g., along the fin active region 101-1), and the cross-sectional view 1850 of FIG. 18B is taken along the line B-B in the top-down view 1855 of FIG. 18C (e.g., across the gate regions 103-1, 103-2 and 103-3). FIGS. 18D, 18E and 18F show respective cross-sectional views 1860, 1865 and 1870 of the control circuit region of the semiconductor structure, with FIG. 18G showing a top-down view 1875 illustrating where the cross-sectional views 1860, 1865 and 1870 are taken in the control circuit region of the semiconductor structure. The cross-sectional view 1860 of FIG. 18D is taken along the line D-D in the top-down view 1875 of FIG. 18G (e.g., along the fin active region 101-3), the cross-sectional view 1865 of FIG. 18E is taken along the line E-E in the top-down view 1875 of FIG. 18G (e.g., along the gate region 103-5), and the cross-sectional view 1870 of FIG. 18F is taken along the line F-F in the top-down view 1875 of FIG. 18G (e.g., between the gate regions 103-5 and 103-6 across the fin active regions 101-2 and 101-3). FIGS. 18H and 18I show respective cross-sectional views 1890 and 1893 of the ESD-transient detection circuit region of the semiconductor structure, with FIG. 18J showing a top-down view 1895 illustrating where the cross-sectional views 1890 and 1893 are taken in the ESD-transient detection circuit region of the semiconductor structure. The cross-sectional view 1890 of FIG. 18H is taken along the line H-H in the top-down view 1895 of FIG. 18J (e.g., across the dummy gate regions 103-7 and 103-8 where the connection 105-7 to the power rail is formed), and the cross-sectional view 1893 of FIG. 18I is taken along the line I-I in the top-down view 1895 of FIG. 18J (e.g., across the dummy gate regions 103-7 and 103-8 where connections 105-6 and 105-8 to the resistor are formed).

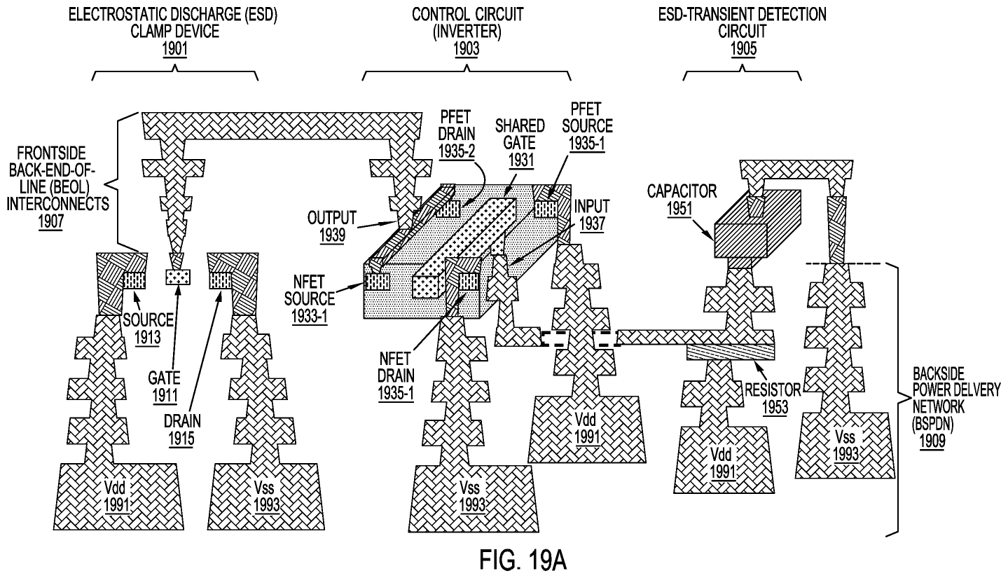

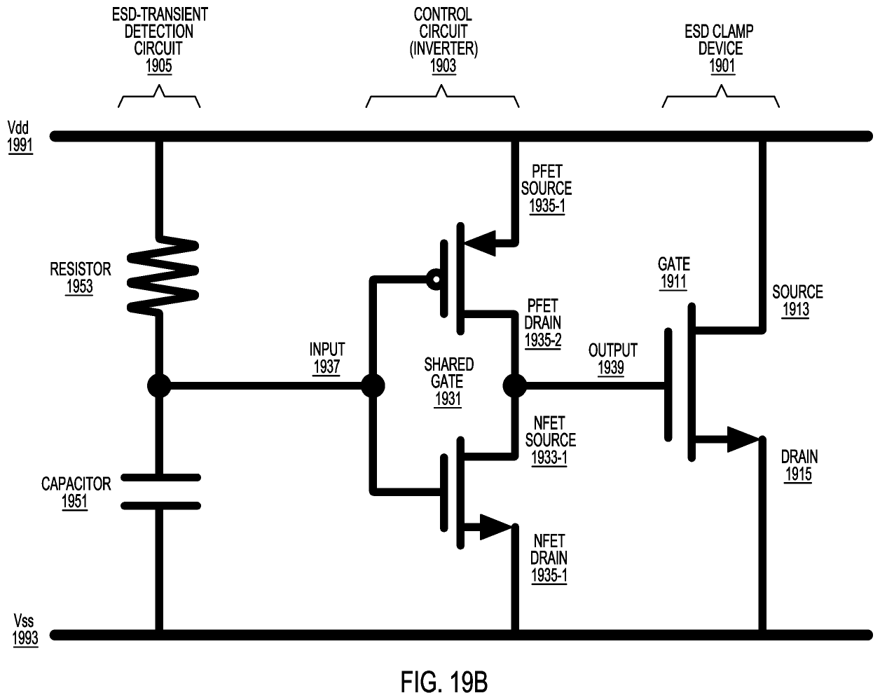

FIGS. 19A and 19B show a structure formed using the process flow of FIGS. 1A-18J. FIG. 19A shows an ESD claim device 1901 (e.g., a high current capacity transistor), a control circuit 1903 (e.g., an inverter), and an ESD-transient detection circuit 1905 (e.g., an RC device). FIG. 19A also shows frontside BEOL interconnects 1907 and a BSPDN 1909. The ESD clamp device 1901 includes a gate 1911, source 1913 and drain 1915. The control circuit 1903 includes a shared gate 1931, an NFET source 1933-1, an NFET drain 1935-1, a PFET source 1935-1, a PFET drain 1935-2, an input 1937, and an output 1939. The ESD-transient detection circuit 1905 includes a capacitor 1951 and resistor 1953. The gate 1911 of the ESD clamp device 1901 is coupled, via the frontside BEOL interconnects 1907, to the output 1939 of the control circuit 1903. The source 1913 of the ESD clamp device 1901 is coupled to a Vdd power rail 1991 (e.g., a positive supply voltage) via the BSPDN 1909. The drain 1915 of the ESD clamp device 1901 is coupled to a Vss power rail 1993 (e.g., ground) via the BSPDN 1909. The PFET source 1935-1 is coupled to the Vdd power rail 1991 via the BSPDN 1909, and the NFET drain 1935-1 is coupled to the Vss power rail 1993 via the BSPDN 1909. The input 1937 of the control circuit 1903 is coupled to the resistor 1953 of the ESD-transient detection circuit 1905 via the BSPDN 1909. The resistor 1953 is coupled to both the Vdd power rail 1991 and a bottom electrode of the capacitor 1951 via the BSPDN 1909. A top electrode of the capacitor 1951 is coupled to the Vss power rail 1993 via the frontside BEOL interconnects 1907 and the BSPDN 1909. FIG. 19B shows a circuit diagram for the structure shown in FIG. 19A.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

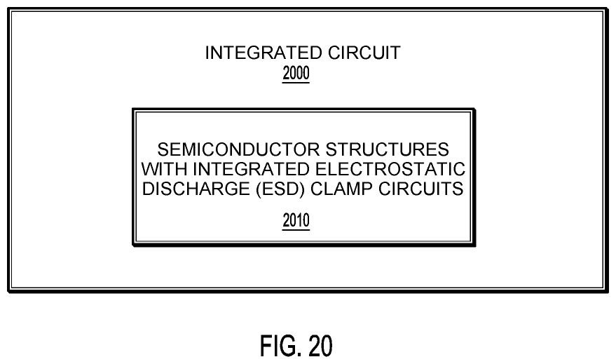

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 20 shows an example integrated circuit 2000 which includes one or more semiconductor structures with integrated ESD clamp circuits 2010.

In some embodiments, a semiconductor structure comprises a transistor device at a first side of the semiconductor structure, a control circuit at the first side of the semiconductor structure, and an RC circuit comprising a resistor and a capacitor. The resistor is in a power delivery network at a second side of the semiconductor structure and the capacitor is at the first side of the semiconductor structure. A first electrode of the capacitor is coupled to a first power rail in the power delivery network at the second side of the semiconductor structure. A second electrode of the capacitor is coupled to a second power rail in the power delivery network at the second side of the semiconductor structure. An input of the control circuit is coupled to the resistor. A gate of the transistor device is coupled to an output of the control circuit.

The first power rail may be coupled to a ground voltage and the second power rail may be coupled to a positive supply voltage.

A source of the transistor device may be coupled to the first power rail and a drain of the transistor device may be coupled to the second power rail.

The first electrode of the capacitor may be coupled to the first power rail through at least one via interconnecting the first power rail and one or more BEOL interconnects at the first side of the structure.

The gate of the transistor device may be coupled to the output of the control circuit through one or more BEOL interconnects at the first side of the semiconductor structure.

The input of the control circuit may be coupled to the resistor through one or more vias formed through an STI region.

The resistor may have a first surface and a second surface opposite the first surface, the first surface of the resistor being coupled to the first electrode of the capacitor and the second surface of the resistor being coupled to the first power rail.

The capacitor may comprise a MIM capacitor.

The control circuit may comprise an inverter. The inverter may comprise a CMOS inverter comprising a p-type transistor and an n-type transistor with a shared gate, wherein a source of the p-type transistor is coupled to the first power rail, wherein a drain of the n-type transistor is coupled to the second power rail, and wherein the shared gate provides an input coupled to the resistor.

The transistor device may comprise a nanosheet transistor structure.

The transistor device may be coupled, in parallel with one or more additional transistor devices, between the first power rail and the second power rail.

In some embodiments, an ESD clamp circuit comprises an RC circuit, a control circuit, and an ESD clamp device. The RC circuit comprises a resistor in a BSPDN and a capacitor at a frontside of the ESD clamp circuit. The capacitor has a first electrode coupled to a first power rail in the BSPDN and a second electrode coupled to a first surface of the resistor. A second surface of the resistor, opposite the first surface of the resistor, is coupled to a second power rail in the BSPDN. An input of the control circuit is coupled to the resistor. The ESD clamp device is coupled to an output of the control circuit.

The control circuit may comprise a CMOS inverter.

The ESD clamp device may comprise a transistor device coupled between the first power rail and the second power rail.

The ESD clamp device may comprise two or more transistor devices connected in parallel between the first power rail and the second power rail.

In some embodiments, an integrated circuit comprises an ESD clamp circuit structure comprising a transistor device at a first side of the ESD clamp circuit structure, a control circuit at the first side of the ESD clamp circuit structure, and an RC circuit comprising a resistor and a capacitor. The resistor is in a power delivery network at a second side of the ESD clamp circuit structure and the capacitor is at the first side of the ESD clamp circuit structure. A first electrode of the capacitor is coupled to a first power rail in the power delivery network at the second side of the ESD clamp circuit structure. A second electrode of the capacitor is coupled to a second power rail in the power delivery network at the second side of the ESD clamp circuit structure. An input of the control circuit is coupled to the resistor. A gate of the transistor device is coupled to an output of the control circuit.

The first power rail may be coupled to a ground voltage and the second power rail may be coupled to a positive supply voltage.

The input of the control circuit may be coupled to the resistor through one or more vias formed through an STI region.

The resistor may have a first surface and a second surface opposite the first surface, the first surface of the resistor being coupled to the first electrode of the capacitor and the second surface of the resistor being coupled to the first power rail.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a transistor device at a first side of the semiconductor structure;
a control circuit at the first side of the semiconductor structure; and
a resistor-capacitor circuit comprising a resistor and a capacitor;
wherein the resistor is in a power delivery network at a second side of the semiconductor structure and the capacitor is at the first side of the semiconductor structure;
wherein a first electrode of the capacitor is coupled to a first power rail in the power delivery network at the second side of the semiconductor structure;
wherein a second electrode of the capacitor is coupled to a second power rail in the power delivery network at the second side of the semiconductor structure;
wherein an input of the control circuit is coupled to the resistor; and
wherein a gate of the transistor device is coupled to an output of the control circuit.

2. The semiconductor structure of claim 1, wherein the first power rail is coupled to a ground voltage and the second power rail is coupled to a positive supply voltage.

3. The semiconductor structure of claim 1, wherein a source of the transistor device is coupled to the first power rail and a drain of the transistor device is coupled to the second power rail.

4. The semiconductor structure of claim 1, wherein the first electrode of the capacitor is coupled to the first power rail through at least one via interconnecting the first power rail and one or more back-end-of-line interconnects at the first side of the structure.

5. The semiconductor structure of claim 1, wherein the gate of the transistor device is coupled to the output of the control circuit through one or more back-end-of-line interconnects at the first side of the semiconductor structure.

6. The semiconductor structure of claim 1, wherein the input of the control circuit is coupled to the resistor through one or more vias formed through a shallow trench isolation region.

7. The semiconductor structure of claim 1, wherein the resistor has a first surface and a second surface opposite the first surface, the first surface of the resistor being coupled to the first electrode of the capacitor and the second surface of the resistor being coupled to the first power rail.

8. The semiconductor structure of claim 1, wherein the capacitor comprises a metal-insulator-metal capacitor.

9. The semiconductor structure of claim 1, wherein the control circuit comprises an inverter.

10. The semiconductor structure of claim 9, wherein the inverter comprises a complementary metal-oxide-semiconductor inverter comprising a p-type transistor and an n-type transistor with a shared gate, wherein a source of the p-type transistor is coupled to the first power rail, wherein a drain of the n-type transistor is coupled to the second power rail, and wherein the shared gate provides an input coupled to the resistor.

11. The semiconductor structure of claim 1, wherein the transistor device comprises a nanosheet transistor structure.

12. The semiconductor structure of claim 1, wherein the transistor device is coupled, in parallel with one or more additional transistor devices, between the first power rail and the second power rail.

13. An electrostatic discharge clamp circuit, comprising:
a resistor-capacitor circuit;
a control circuit; and
an electrostatic discharge clamp device;
wherein the resistor-capacitor circuit comprises a resistor in a backside power delivery network and a capacitor at a frontside of the electrostatic discharge clamp circuit;
wherein the capacitor has a first electrode coupled to a first power rail in the backside power delivery network;
wherein the capacitor has a second electrode coupled to a first surface of the resistor;
wherein a second surface of the resistor, opposite the first surface of the resistor, is coupled to a second power rail in the backside power delivery network;
wherein an input of the control circuit is coupled to the resistor; and
wherein the electrostatic discharge clamp device is coupled to an output of the control circuit.

14. The electrostatic discharge clamp circuit of claim 13, wherein the control circuit comprises a complementary metal-oxide-semiconductor inverter.

15. The electrostatic discharge clamp circuit of claim 13, wherein the electrostatic discharge clamp device comprises a transistor device coupled between the first power rail and the second power rail.

16. The electrostatic discharge clamp circuit of claim 13, wherein the electrostatic discharge clamp device comprises two or more transistor devices connected in parallel between the first power rail and the second power rail.

17. An integrated circuit comprising:
an electrostatic discharge clamp circuit structure comprising:
a transistor device at a first side of the electrostatic discharge clamp circuit structure;
a control circuit at the first side of the electrostatic discharge clamp circuit structure; and
a resistor-capacitor circuit comprising a resistor and a capacitor;
wherein the resistor is in a power delivery network at a second side of the electrostatic discharge clamp circuit structure and the capacitor is at the first side of the electrostatic discharge clamp circuit structure;
wherein a first electrode of the capacitor is coupled to a first power rail in the power delivery network at the second side of the electrostatic discharge clamp circuit structure;
wherein a second electrode of the capacitor is coupled to a second power rail in the power delivery network at the second side of the electrostatic discharge clamp circuit structure;
wherein an input of the control circuit is coupled to the resistor; and
wherein a gate of the transistor device is coupled to an output of the control circuit.

18. The integrated circuit of claim 17, wherein the first power rail is coupled to a ground voltage and the second power rail is coupled to a positive supply voltage.

19. The integrated circuit of claim 17, wherein the input of the control circuit is coupled to the resistor through one or more vias formed through a shallow trench isolation region.

20. The integrated circuit of claim 17, wherein the resistor has a first surface and a second surface opposite the first surface, the first surface of the resistor being coupled to the first electrode of the capacitor and the second surface of the resistor being coupled to the first power rail.
